(19) United States
(12) Patent Application Publication
(10) Pub. No.: US 2026/0243714 A1
(43) Pub. Date: Aug. 20, 2026

(54) MRI HAPLOID SORTING SYSTEM

(71) Applicant: Monsanto Technology LLC, Creve Coeur, MO (US)

(72) Inventors: Jared BAKER, Creve Coeur, MO (US); Jacob BERGFELD, Creve Coeur, MO (US); Joshua W. HIGGINS, Creve Coeur, MO (US); Andrew MADDUX, Creve Coeur, MO (US); Dustin SMITH, Creve Coeur, MO (US)

(21) Appl. No.: 19/057,034

(22) Filed: Feb. 19, 2025

Related U.S. Application Data
(63) Continuation of application No. PCT/US2025/015337, filed on Feb. 11, 2025.

(51) Int. Cl. G01N 24/08; G01N 35/10

(52) U.S. Cl. CPC G01N 24/082; G01N 35/1095; G01N 2035/1027

(57) ABSTRACT

A high throughput small object sorting system comprising a system controller for controlling operation of the sorting system, a singulating and data collection subsystem comprising am MRI device, a singulator hopper, and a singulator for parsing the small objects one-by-one from the singulator hopper and dropping each small object into the MRI device such that each small object free-falls through the MRI device. The MRI device configured to receive each small object, determine total mass data and oil mass data of each small, and communicate the total mass and oil mass data to the system controller as each small object free-falls through the MRI device. The system further comprising a parsing subsystem configured to direct each small object to one of a discard bin, an affirmatively identified small object container, a tentatively identified small object container, or an elevator hopper based on an oil content of each small object.

### FIELD

The present disclosure relates generally to magnetic resonance imaging (MRI) systems and methods for measuring oil and/or moisture content of small object samples (e.g., seed samples). More particularly, it relates to automated systems and methods for using NMR technology for the high-throughput continuous sorting of small objects (e.g., seeds) based on the oil and/or moisture content.

### BACKGROUND

Magnetic resonance imaging methods such as, low-field nuclear magnetic resonance (NMR) relaxometry, have been implemented in many analytical applications. For example, NMR has been utilized in determining oil and/or moisture content in small objects, such as seeds, measuring xylene solubility in polyethylene, and determining the solid to liquid fat ratio in margarine. However, despite its wide use in analytical laboratories for nondestructive oil measurement, known NMR based small object (e.g., seeds) analytic methods require an undesirably long time for an individual measurement.

### SUMMARY

The present disclosure generally provides system and method for high-throughput sorting of small objects (e.g., seeds) based on oil and/or moisture content of the small objects using magnetic resonance imaging (MRI).

In various embodiments, the present disclosure provides a high throughput small object sorting system, wherein the system comprises a system controller structured and operable to control operation of the sorting system and a singulating and data collection subsystem. The singulating and data collection subsystem comprises a magnetic resonance imaging (MRI) device, a singulator hopper structured and operable to receive the subject small objects from elevator hopper, and a singulator structured and operable to parse the small objects one-by-one from the singulator hopper and drop each small object into the MRI device such that each small object free-falls into and through the MRI device. The magnetic resonance imaging (MRI) device is structured and operable to receive each small object from the singulator, determine total mass data and oil mass data of each small object received by the MRI device, and communicate the total mass and oil mass data for each small object received by the MRI device to the system controller as each small object free-falls through the MRI device. The system further comprises a parsing subsystem that comprises a diverter assembly structured and operable to direct each small object to one of a discard bin, an affirmatively identified small object container, a tentatively identified small object container, or the elevator hopper based on an oil content of each small object determined by the system controller utilizing the total mass and oil mass data.

In various other embodiments, the present disclosure provides a method for high throughput small object sorting, wherein the method comprises, during a first-pass sorting operation of a high throughput small object sorting system, one-by-one parsing subject small objects from a subject batch of small objects, dropping each parsed subject small objects into an MRI device of the small object sorting system such that each parsed subject small objects free-falls through the MRI device, and collecting total mass data and an oil mass data for each parsed subject small object as each parsed subject small object free-falls through the MRI device. The method additionally comprises, in real time as each subject small object free-falls through the MRI device, calculating an oil content of each subject small object, via an system controller of the high throughput small object sorting system, via execution of a sorting algorithm by a system controller, determining whether the oil content of each subject small object is one of within a first-pass target range and within a first-pass non-target range, and collecting the subject small objects that have an oil content within the first-pass target range to obtain a first-pass batch of small objects, and discarding the subject small objects that have an oil content with the first-pass non-target range. The method further comprises, during a second-pass sorting operation of a high throughput small object sorting system, one-by-one parsing first-pass small objects from the first-pass batch of small objects, dropping each parsed first-pass small objects into the MRI device such that each parsed first-pass small objects free-falls through the MRI device, and collecting total mass data and an oil mass data for each parsed first-pass small object as each parsed first-pass small object free-falls through the MRI device. The method still further comprises, in real time as each first-pass small object free-falls through the MRI device, calculating an oil content of each subject small object, via the system controller, via execution of the sorting algorithm by a system controller, determining whether the oil content of each first-pass small object is one of within a second-pass target range and within a second-pass non-target range, and collecting the first-pass small objects that have an oil content within the second-pass target range in an affirmatively identified small object container, and collecting the first-pass small objects that have an oil content within the second-pass non-target range in a tentatively identified small object container.

In yet other embodiments the present disclosure provides a high throughput small object sorting system, wherein the system comprises an input/output console that comprises an input hopper structured and operable to receive a batch of small object for input into the sorting system, and a system controller structured and operable to control operation of the sorting system. The system additionally comprises an elevator subsystem that comprises an elevator hopper structured and operable to receive the batch of small objects from the input hopper; and a conveyor structured and operable to convey elevator hopper from a loading position to an offloading position. The system further comprise a singulating and data collection subsystem that comprises a magnetic resonance imaging (MRI) device, a singulator hopper structured and operable to receive the subject small objects from elevator hopper, and a singulator structured and operable to parse the small objects one-by-one from the singulator hopper and drop each small object into the MRI device such that each small object free-falls into and through the MRI device. In various instances the magnetic resonance imaging (MRI) device structured and operable to receive each small object from the singulator, determine total mass data and oil mass data of each small object received by the MRI device, and communicate the total mass and oil mass data for each small object received by the MRI device to the system controller as each small object free-falls through the MRI device. The system still further comprises a parsing subsystem that comprises a diverter assembly structured and operable to direct each small object to one of a discard bin, an affirmatively identified small object container, a tentatively identified small object container, or the elevator hopper based on an oil content of each small object determined by the system controller utilizing the total mass and oil mass data.

This summary is provided merely for purposes of summarizing various example embodiments of the present disclosure so as to provide a basic understanding of various aspects of the teachings herein. Various embodiments, aspects, and advantages will become apparent from the following detailed description taken in conjunction with the accompanying drawings which illustrate, by way of example, the principles of the described embodiments. Accordingly, it should be understood that the description and specific examples set forth herein are intended for purposes of illustration only and are not intended to limit the scope of the present teachings.

### BRIEF DESCRIPTION OF DRAWINGS

The drawings described herein are for illustration purposes only and are not intended to limit the scope of the present teachings in any way.

FIG. 1 is an exemplary isometric view of a high throughput small object sorting system, in accordance with various embodiments of the present disclosure.

FIG. 2A is an exemplary illustration of an input and output console of the sorting system shown in FIG. 1, in accordance with various embodiments of the present disclosure.

FIG. 2B is an exemplary illustration of an interior of a wall of a housing of the sorting system shown in FIG. 1 having a small object input hopper mounted to an exterior thereof, in accordance with various embodiments of the present disclosure.

FIG. 3A is an exemplary illustration of the elevator subsystem of the sorting system shown in FIG. 1, in accordance with various embodiments of the present disclosure.

FIG. 3B is an exemplary illustration of the elevator subsystem shown in FIG. 3A disposed in an elevator subsystem cabinet of the sorting system, and having an elevator hopper disposed in a lower or receiving position, in accordance with various embodiments of the present disclosure.

FIG. 3C is an exemplary illustration of the elevator subsystem shown in FIGS. 3A and 3B disposed in the elevator subsystem cabinet, and having the elevator hopper disposed in an upper or dispensing position, in accordance with various embodiments of the present disclosure.

FIG. 4 is an exemplary illustration of a singulating and data collection subsystem of the sorting system shown in FIG. 1, in accordance with various embodiments of the present disclosure.

FIG. 5A is an exemplary illustration of a parsing subsystem of the sorting system shown in FIG. 1, in accordance with various embodiments of the present disclosure.

FIG. 5B is an exemplary illustration of the parsing system shown in FIG. 5A disposed within a parsing subsystem cabinet and illustrating small object parsing paths for a first-pass sorting operation of the sorting system shown in FIG. 1, in accordance with various embodiments of the present disclosure.

FIG. 5C is an exemplary illustration of the parsing system shown in FIG. 5A disposed within the parsing subsystem cabinet and illustrating small object parsing paths for a second-pass sorting operation of the sorting system shown in FIG. 1, in accordance with various embodiments of the present disclosure.

FIG. 5D is an exemplary illustration of the parsing system shown in FIG. 5A disposed within a parsing subsystem cabinet and illustrating small object parsing paths for a first-pass sorting operation of the sorting system shown in FIG. 1, in accordance with various other embodiments of the present disclosure.

FIG. 5E is an exemplary illustration of the parsing system shown in FIG. 5A disposed within the parsing subsystem cabinet and illustrating small object parsing paths for a second-pass sorting operation of the sorting system shown in FIG. 1, in accordance with various other embodiments of the present disclosure.

FIG. 5F is an exemplary illustration of a diverting device of the parsing system in accordance with various embodiments of the present disclosure.

FIG. 6 is block diagram of a computer based system controller of the sorting system shown in FIG. 1, in accordance with various embodiments of the present disclosure.

FIG. 7 is a block diagram of a small object batch container or bag having an ID tag affixed thereto, in accordance with various embodiments of the present disclosure.

FIGS. 8 and 8A are a flow chart exemplarily illustrating the first-pass analysis and sorting operation of the high throughput small object sorting system shown in FIGS. 1 through 7, in accordance with various embodiments of the present disclosure.

FIG. 9 is a flow chart exemplarily illustrating a second-pass analysis and sorting operation of the high throughput small object sorting system shown in FIGS. 1 through 7, in accordance with various embodiments of the present disclosure.

FIG. 10 is an exemplary graph illustrating implementation of a first sorting algorithm executed by the system controller to sort a subject batch of small objects based on oil content of each respective individual subject batch small object during the first-pass sorting operation of the sorting system shown in FIG. 1, in accordance with various embodiments of the present disclosure.

FIG. 11 is an exemplary graph illustrating implementation of a second sorting algorithm executed by the system controller to sort a first-pass batch of small objects based on oil content of each respective individual subject first-pass small object during a second-pass sorting operation of the sorting system shown in FIG. 1, in accordance with various embodiments of the present disclosure.

Corresponding reference numerals indicate corresponding parts throughout the several views of drawings.

### DETAILED DESCRIPTION

The following description is merely exemplary in nature and is in no way intended to limit the present teachings, application, or uses. Throughout this specification, like reference numerals will be used to refer to like elements. Additionally, the embodiments disclosed below are not intended to be exhaustive or to limit the invention to the precise forms disclosed in the following detailed description. Rather, the embodiments are chosen and described so that others skilled in the art can utilize their teachings. As well, it should be understood that the drawings are intended to illustrate and plainly disclose presently envisioned embodiments to one of skill in the art, but are not intended to be manufacturing level drawings or renditions of final products and may include simplified conceptual views to facilitate understanding or explanation. As well, the relative size and arrangement of the components may differ from that shown and still operate within the spirit of the invention.

As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to practice the disclosure and are not intended to limit the scope of the appended claims.

Unless otherwise defined, all technical and scientific terms used herein have the same meaning as commonly understood by one of ordinary skill in the art to which this disclosure belongs. The terminology used herein is for the purpose of describing particular example embodiments only and is not intended to be limiting. As used herein, the singular forms “a”, “an”, and “the” may be intended to include the plural forms as well, unless the context clearly indicates otherwise. The terms “comprises”, “comprising”, “including”, and “having” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps can be employed.

When an element, object, device, apparatus, component, region or section, etc., is referred to as being “on”, “engaged to or with”, “connected to or with”, or “coupled to or with” another element, object, device, apparatus, component, region or section, etc., it can be directly on, engaged, connected or coupled to or with the other element, object, device, apparatus, component, region or section, etc., or intervening elements, objects, devices, apparatuses, components, regions or sections, etc., can be present. In contrast, when an element, object, device, apparatus, component, region or section, etc., is referred to as being “directly on”, “directly engaged to”, “directly connected to”, or “directly coupled to” another element, object, device, apparatus, component, region or section, etc., there may be no intervening elements, objects, devices, apparatuses, components, regions or sections, etc., present. Other words used to describe the relationship between elements, objects, devices, apparatuses, components, regions or sections, etc., should be interpreted in a like fashion (e.g., “between” versus “directly between”, “adjacent” versus “directly adjacent”, etc.).

As used herein the phrase “operably connected to” will be understood to mean two are more elements, objects, devices, apparatuses, components, etc., that are directly or indirectly connected to each other in an operational and/or cooperative manner such that operation or function of at least one of the elements, objects, devices, apparatuses, components, etc., imparts or causes operation or function of at least one other of the elements, objects, devices, apparatuses, components, etc. Such imparting or causing of operation or function can be unilateral or bilateral.

As used herein, the term “and/or” includes any and all combinations of one or more of the associated listed items. For example, A and/or B includes A alone, or B alone, or both A and B.

Although the terms first, second, third, etc. can be used herein to describe various elements, objects, devices, apparatuses, components, regions or sections, etc., these elements, objects, devices, apparatuses, components, regions or sections, etc., should not be limited by these terms. These terms may be used only to distinguish one element, object, device, apparatus, component, region or section, etc., from another element, object, device, apparatus, component, region or section, etc., and do not necessarily imply a sequence or order unless clearly indicated by the context.

Moreover, it will be understood that various directions such as “upper”, “lower”, “bottom”, “top”, “left”, “right”, “first”, “second” and so forth are made only with respect to explanation in conjunction with the drawings, and that components may be oriented differently, for instance, during transportation and manufacturing as well as operation. Because many varying and different embodiments may be made within the scope of the concept(s) taught herein, and because many modifications may be made in the embodiments described herein, it is to be understood that the details herein are to be interpreted as illustrative and non-limiting.

The apparatuses/systems and methods described herein can be implemented at least in part by one or more computer program products comprising one or more non-transitory, tangible, computer-readable mediums storing computer programs with instructions that may be performed by one or more processors. The computer programs may include processor executable instructions and/or instructions that may be translated or otherwise interpreted by a processor such that the processor may perform the instructions. The computer programs can also include stored data. Non-limiting examples of the non-transitory, tangible, computer readable medium are nonvolatile memory, magnetic storage, and optical storage.

As used herein, the term module can refer to, be part of, or include an application specific integrated circuit (ASIC); an electronic circuit; a combinational logic circuit; a field programmable gate array (FPGA); a processor (shared, dedicated, or group) that performs instructions included in code, including for example, execution of executable code instructions and/or interpretation/translation of uncompiled code; other suitable hardware components that provide the described functionality; or a combination of some or all of the above, such as in a system-on-chip. The term module can include memory (shared, dedicated, or group) that stores code executed by the processor.

The term code, as used herein, can include software, firmware, and/or microcode, and can refer to one or more programs, routines, functions, classes, and/or objects. The term shared, as used herein, means that some or all code from multiple modules can be executed using a single (shared) processor. In addition, some or all code from multiple modules can be stored by a single (shared) memory. The term group, as used above, means that some or all code from a single module can be executed using a group of processors. In addition, some or all code from a single module can be stored using a group of memories.

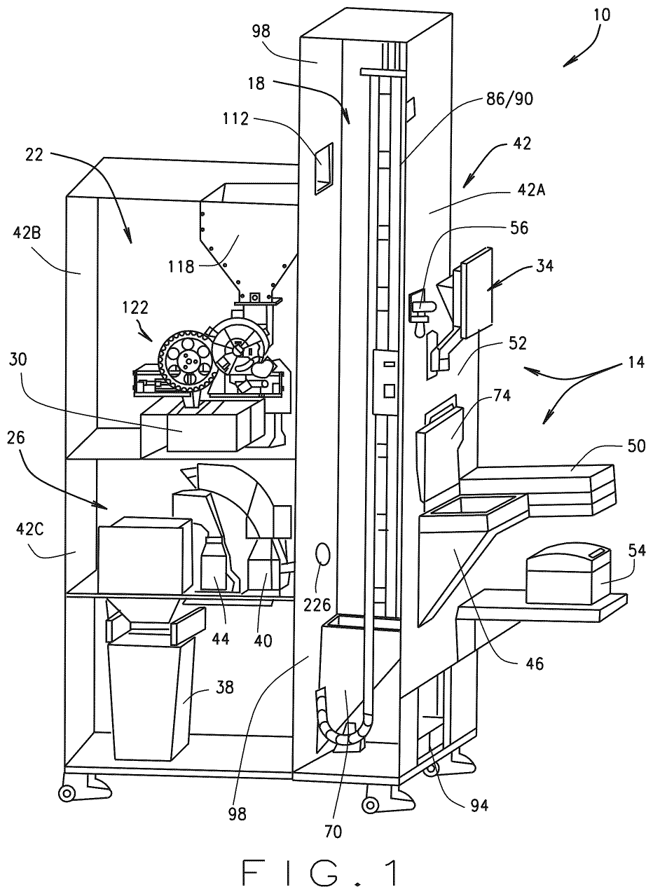

Referring now to FIG. 1, the present disclosure provides a high throughput dynamic small object sorting system 10 (referred to herein as the sorting system 10) that utilizes magnetic resonance imaging (MRI) to sort small objects based on oil and/or moisture content and/or the content of various other constituents and/or elements of the small object such as starch and/or protein content. For example, in various embodiments, the small object can comprise seeds, grain, or other plant product, oilseeds, cereals and legumes such as wheat, corn, rye, soybeans, oats, rice, millet, canola, etc., and the sorting system 10 can utilize magnetic resonance imaging (MRI) to sort seeds based on oil and/or moisture and/or starch and/or protein content and/or any other constituent and/or elements of the seed. However, for simplicity, the present disclosure will described the sorting system 10 with regard to oil and/or moisture content.

Generally, the sorting system 10 includes an input and output (input/output) console 14, an elevator subsystem 18, a singulating and data collection subsystem 22, a parsing subsystem 26. The input/output console 14 is generally structured and operable to provide the following: 1) a means to input independent subject batches of small objects into the sorting system 10 (each subject batch can comprise a plurality of small objects), 2) a means to input subject batch information and data specific to each subject batch of small objects input into the sorting system 10; and 3) a means to output phenotypical and genotypical data collected and/or generated by the sorting system 10 that is specific to one or more subset of small objects that is parsed from each subject batch of small objects by the sorting system based on phenotypical and genotypical data collected and/or generated by the sorting system 10. Each subject batch of small objects can comprise a predetermined number and/or type and/or grouping of small objects having one or more predetermined trait. For example, each subject batch of small objects can comprise a predetermined number of soybean or corn seeds (or any other type of seed), engineered to be draught or insect resistant (or have any other trait) that were harvested from a particular test plot of a particular field (or any other grouping). As used herein, the term “batch” of small objects will be understood to mean a select plurality of small objects.

The elevator subsystem 18 is generally structured and operable to: 1) receive each independent predetermined subject batch of small objects from the input/output console for a first-pass analysis and sorting by the sorting system 10 14; 2) transport each subject batch of small objects to the singulating and data collection subsystem 22 for first-pass singulating when the sorting system 10 is in a first-pass parsing mode. The singulating and data collection system 22 is generally structured and operable to: 1) receive the subject batch of small objections from the elevator subsystem 18 for first-pass singulating (i.e., parsing the small objects one-by-one from the batch of small objects); 2) singulate the plurality of small objects in the subject batch of small objects; 3) drop, via gravity, each singulated subject batch small object through a magnetic resonance imaging (MRI) device 30 of the singulating and data collection subsystem 22; 4) collect, via the MRI device 30, oil and/or moisture mass content data of each singulated subject batch small object (e.g., oil and/or moisture mass data for each singulated subject batch small object); 5) collect, via the MRI device 30, total mass data of each singulated subject batch small object; and 6) communicate the collected oil and/or moisture content data and the total mass data of each subject batch singulated small object to a computer-based system controller 34 of the sorting system 10.

The parsing subsystem 26 is generally structured and operable to: 1) receive each singulated subject batch small object that has been dropped through the MRI device 30; 2) first-pass parse the singulated subject batch of small objects based on whether each singulated subject batch small object has a target oil and/or moisture content. As used herein, the target oil and/or moisture content will be understood to mean an oil and/or moisture content that is within a desired range (e.g., an oil and/or moisture content that is greater than a predetermined lower threshold and less than a predetermined upper threshold); 3) divert or direct the first-pass parsed small objects that have a target oil and/or moisture content back to the elevator subsystem 18, thereby collecting a first-pass batch of small objects to be subjected to a second-pass analysis and sorting by the sorting system 10; and 4) divert or direct the first-pass parsed small objects that that have a non-target oil and/or moisture content into a discard bin 38, thereby collecting a first-pass batch of small objects to be eliminated from further analysis by the sorting system 10.

The elevator subsystem 18 is further generally structured and operable to: 1) receive the first-pass batch of small objects from the parsing subsystem 26 that have been determined, via operation of the singulating and data collection subsystem 22 and the parsing subsystem 26, to have a target oil and/or moisture content and therefore require second-pass analysis and sorting by the sorting system 10; and 2) transport each such first-pass batch of small objects back to the singulating and data collection subsystem 22 for second-pass parsing. The singulating and data collection system 22 is further generally structured and operable to: 1) receive each first-pass batch of small objections from the elevator subsystem 18 for second-pass parsing; 2) singulate the plurality of small objects in the first-pass batch of small objects; 3) drop, via gravity, each singulated first-pass batch small object through the MRI device 30; 4) collect, via the MRI device 30, oil and/or moisture content data of each singulated first-pass batch small object (e.g., oil and/or moisture mass data for each singulated first-pass batch small object); 5) collect, via the MRI device 30, mass data of each singulated first-pass batch small object; and 6) communicate the collected mass and/or moisture data and the mass data of each first-pass batch singulated small object to the computer-based system controller 34.

The parsing subsystem 26 is further generally structured and operable to: 1) receive each singulated first-pass batch small object that has been dropped through the MRI device 30 for second-pass analysis; 2) second-pass parse the singulated first-pass batch of small objects based on whether each singulated first-pass batch small object, has a target oil and/or moisture content or a non-target oil and/or moisture content; 3) divert or direct the second-pass parsed first-pass batch small objects that have a target oil and/or moisture content into an affirmatively identified small object container 40, thereby collecting a second-pass batch of small objects that affirmatively have a target oil and/or moisture content level; and 4) divert or direct the second-pass parsed first-pass batch small objects that that have a non-target oil and/or moisture content that into a tentatively identified container 44, thereby collecting a second-pass batch of small objects that tentatively have a target oil and/or moisture content level.

The system controller 34 is structured and operable to directly or indirectly control and coordinate the automated and cooperative functions and operations of the input/output console 14, the elevator subsystem 18, singulating and data collection subsystem 22, and the parsing subsystem 26, as described below. The system controller 34 is further structured and operable to execute one or more system control and oil and/or moisture content analysis program(s) or algorithm(s) (simply referred to herein as the system control and oil/moisture content analysis software) for analyzing data generated and collected by the singulating and data collection subsystem 22 to identify and separate small objects (e.g., separate haploid seeds from diploid seeds) based on oil and/or moisture content, at a high rate of speed, e.g., 5 to 30 milliseconds/small object, as also described further below.

In various embodiments the sorting system 10 comprises a housing 42 that houses the elevator subsystem 18, the singulating and data collection subsystem 22 and the parsing subsystem 26. In various instances, the housing 42 can be partitioned into one or more cabinet for housing one or more of the elevator subsystem 18, the singulating and data collection subsystem 22 and the parsing subsystem 26. For example, in various embodiments, the housing 42 can be partitioned to comprise: 1) a elevator subsystem cabinet 42A for housing the elevator subsystem 18; 2) a singulating and data collection subsystem cabinet 42B for housing the singulating and data collection subsystem 22; and 3) a parsing subsystem cabinet 42C for housing the parsing subsystem 26. In various instances, one or more of the elevator subsystem cabinet 42A the singulating and data collection subsystem cabinet 42B and the parsing subsystem cabinet 42C can have a door (not shown) hingedly attached there to allow access to the respective elevator subsystem 18, the singulating and data collection subsystem 22, and the parsing subsystem 26 when in an Open position and totally enclose and protect the respective elevator subsystem 18, the singulating and data collection subsystem 22, and the parsing subsystem 26 when in a Closed position.

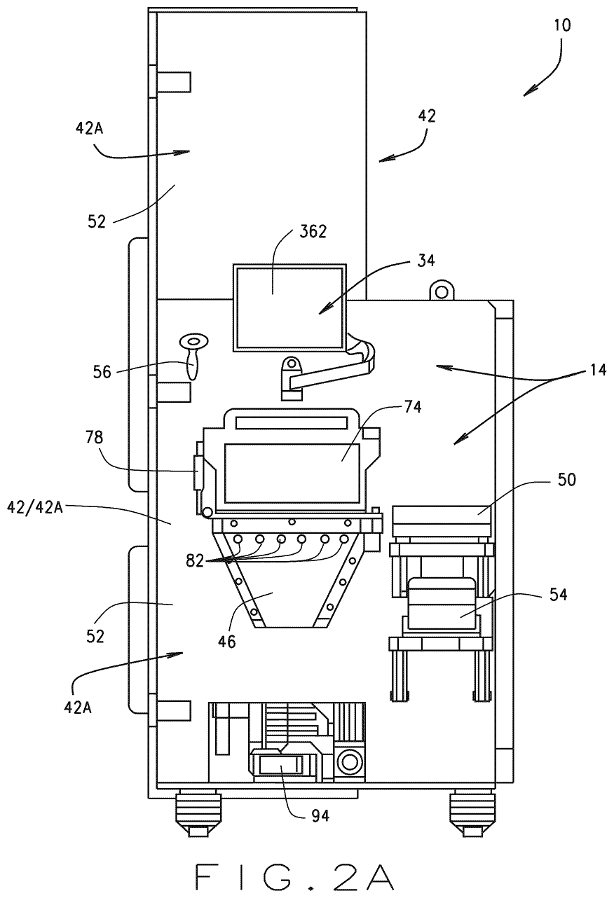

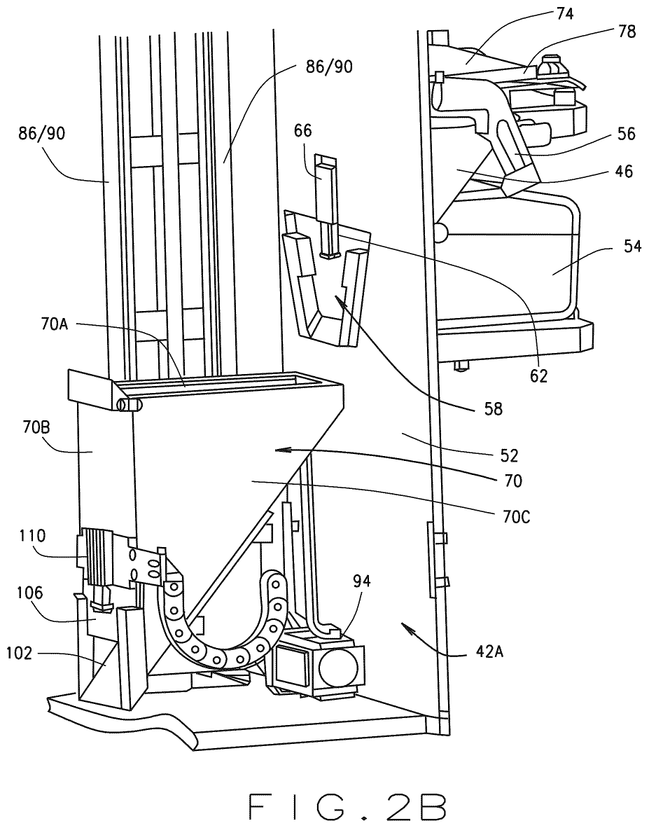

Referring now to FIGS. 1, 2A and 2B, in various embodiments the input/output console 14 comprises an input hopper 46, a scale 50, a label printer 54, an identification (ID) tag scanner or reader 56 (e.g., barcode scanner, QR code reader, RFID reader, etc.) and the computer-based system controller 34. Generally, the computer-based system controller 34 can comprise any computer-based system, such as desktop computer, a laptop computer, a computer tablet, etc. For example, in various embodiments, the system controller can comprise all-in-one touch screen computer having at least one processor, at least one electronic storage device (e.g., a hard drive or equivalent) and a touch screen display that functions as a graphical display and a user input device. The computer-based system controller 34 generally controls all operation of the sorting system 10 via execution of the system control and oil/moisture content analysis software. More particularly, in such embodiments, the system controller 34 controls and coordinates all operations of all components, computers, controllers, programmable circuitry, electrical modules, etc., of the input/output console 14, the elevator subsystem 18, the singulating and data collection subsystem 22 and the parsing subsystem 26 via execution of the system control and oil/moisture content analysis software by the processor(s).

The input hopper 46 generally has a funnel or chute shape having an open top and one or more sidewall that is/are mounted to the exterior of an outer sidewall 52 of the housing 42 (e.g., the exterior of the outer sidewall 52 of the elevator subsystem cabinet 42A). More particularly, the input hopper 46 is mounted to the exterior of the sidewall 52 of the elevator subsystem cabinet 42A such that the input hopper 46 encloses or surrounds an input hopper egress opening 58 that extends through the sidewall 52 of the elevator subsystem cabinet 42A. Accordingly, and interior space of the input hopper 46 is fluidly connected to the egress opening 58. Mounted to the interior of the sidewall 52 of the elevator subsystem cabinet 42A is an input hopper egress opening control door 62 that is connected to an actuator 66 to controllably move the input hopper egress opening control door 62 between an Open position and a Closed position. Particularly, the input hopper egress opening control door actuator 66 is controlled by the system controller 34 (specifically by execution of the system control and oil/moisture content analysis software) to selectably and controllably move input hopper egress opening control door 62 between the Open position and the Closed position. When the input hopper egress opening control door 62 is placed in the Closed position a plurality of small objects can be deposited into and retained within the small object input hopper 46. When the input hopper egress opening control door 62 is controllably and selectably moved from the Closed position to the Open position, the small objects deposited and retained within input hopper 46 will fall through the input hopper egress opening 58 into an elevator hopper 70 as described further below.

In various embodiments, the small object input hopper 46 can comprise a lid 74 that is structured and operable to be movable between an Open position whereby small objects can be deposited and retained within input hopper 46 (as illustrated in FIGS. 1 and 2A) and a Closed position whereby debris or any other unwanted matter is prevented from falling into the input hopper 46 (as illustrated in FIG. 2B). In various instances, the input hopper lid 74 can be controllably and selectively operated by an actuator 78 that is controlled by the system controller 34 (specifically by execution of the system control and oil/moisture content analysis software). Furthermore, in various instances, the input hopper lid 74 can be manually locked or electronically locked via the actuator 78 in the Closed and/or Open position. Furthermore, in various embodiments, the input hopper can include one or more metallic debris magnet 82 that is/are disposed in and extend through one or more wall of the input hopper 46. Each metallic debris magnet 82 can be a permanent magnet or an electromagnet. Each metallic debris magnet 82 is structured and operable to extract, via an attractive magnetic force, ferromagnetic materials (e.g., metallic particles, shavings, filings or any other ferromagnetic debris) that may be disposed in or mixed with a respective subject batch of small objects that has been deposited into the input hopper 46.

The scale 50 is structured and operable to measure the weight and determine the mass of a plurality of small objects to be analyzed by the sorting system 10 (i.e., a subject batch of small objects to be analyzed) prior to depositing the plurality of small objects (e.g., the subject batch of small objects) into the input hopper 46. For example, a subject batch of small objects stored within a bag or other suitable container 214 (wherein the weight/mass of the container is known) can be placed on the scale 50, whereafter the total weight/mass of the subject batch of small objects can be determined by subtracting the weight/mass of the bag/container from the cumulative weight/mass of the subject batch and the bag/container. Subsequently, the total weight/mass of the subject batch of small objects can be manually provided to the system controller 34 for later use in sorting the subject batch of small objects as described below. Alternatively, in various embodiments, the scale 50 can be communicatively connected (wired or wirelessly) to the system controller 34, whereby the system controller 34 receives the weigh/mass of the container (e.g., via the ID tag reader 56) and automatically measures the cumulative weight/mass of the subject batch and the bag/container via the scale 50, and then calculates and automatically stores the total mass of the respective subject batch of small objects for later use in sorting the subject batch of small objects as described below. In various embodiments, as described below, the system controller 34 can receive various other subject batch identification information and data such as, the type of subject batch small objects, genotype and/or phenotype trait information about the subject batch of small objects, geographical location from which the subject batch of small objects originated, etc.

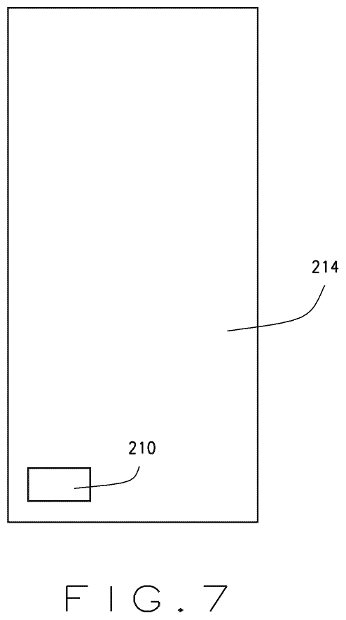

As described above, in various embodiments, each subject batch of small objects can be stored in a bag or other suitable container 214 (FIG. 7). In various instances, each bag/container can include an identification (ID) tag 210 (FIG. 7) such as a barcode label, QR code, RFID tag, etc., that is scannable and readable by the ID tag reader 56. The ID tag reader 56 is communicatively connected (wired or wirelessly) to the control system 34. Hence, prior to placing each subject bath bag/container on the scale 50, an operator can scan the ID tag 210 on the respective subject batch bag/container, via the ID tag reader 56, to input information and data relating to the respect subject batch of small objects provided by the ID tag 210 into to the system controller 34, such as the number and/or type and/or grouping of small objects that are contained in the respective bag/container, and/or display such information and data on a display 362 of the system controller 34. Such information and data can then be stored in a database of the control system 34 and utilized during execution of the system control and oil/moisture content analysis software to sort the small objects as described herein. The label printer 54 is communicatively connected (wired and wirelessly) to the control system 34, whereby upon completion of sorting a batch of small objects, as described herein, the label printer 54 can output or print an ID label (e.g., barcode label, a QR code label, an RFID label, etc.) that provides information and data regarding the resulting sorted and collected batch of target small objects that have an oil and/or moisture content that is within a predetermined target range. Additionally, the label printer 54 can output or print an ID label (e.g., barcode label, a QR code label, an RFID label, etc.) that provides information and data regarding the non-target small objects that do not have an oil and/or moisture content that is within the predetermined target range. More particularly, upon completion of sorting a batch of small objects, the system controller 34 prints, via the printer 54, an ID label providing a barcode, QR code, RFID tag, etc., that comprises information and data regarding the resulting sorted and collected target batch of small objects such as the number of target small objects collected, average oil and/or moisture content per small object, the type of small objects, the grouping of small objects, etc. Subsequently, the ID label can be affixed to the respective bag/container (e.g., the affirmatively identified small object container 40 and the tentatively identified small object container 44).

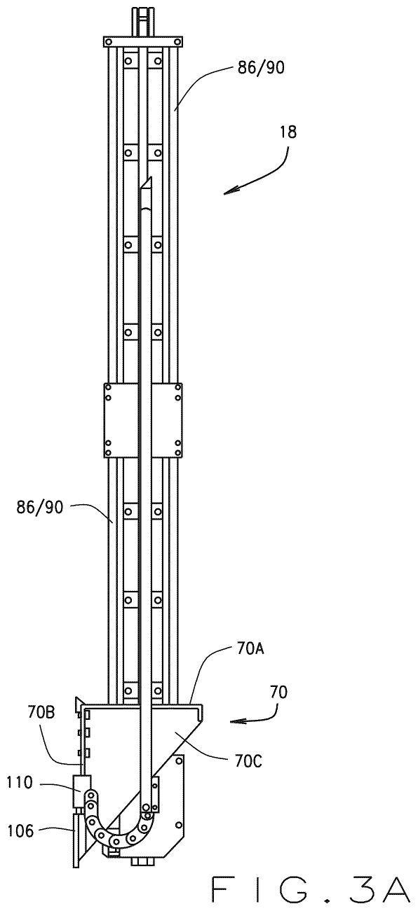

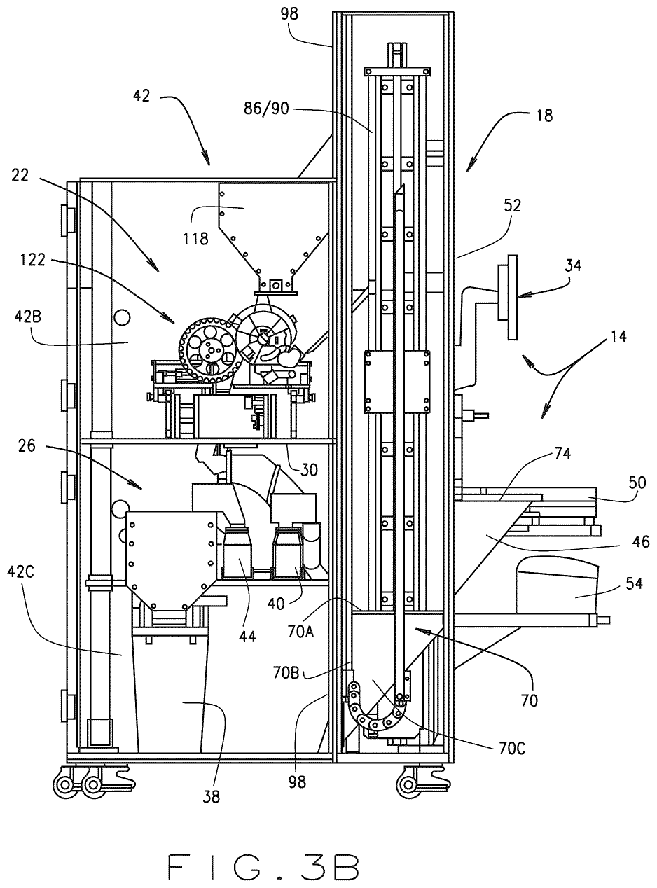

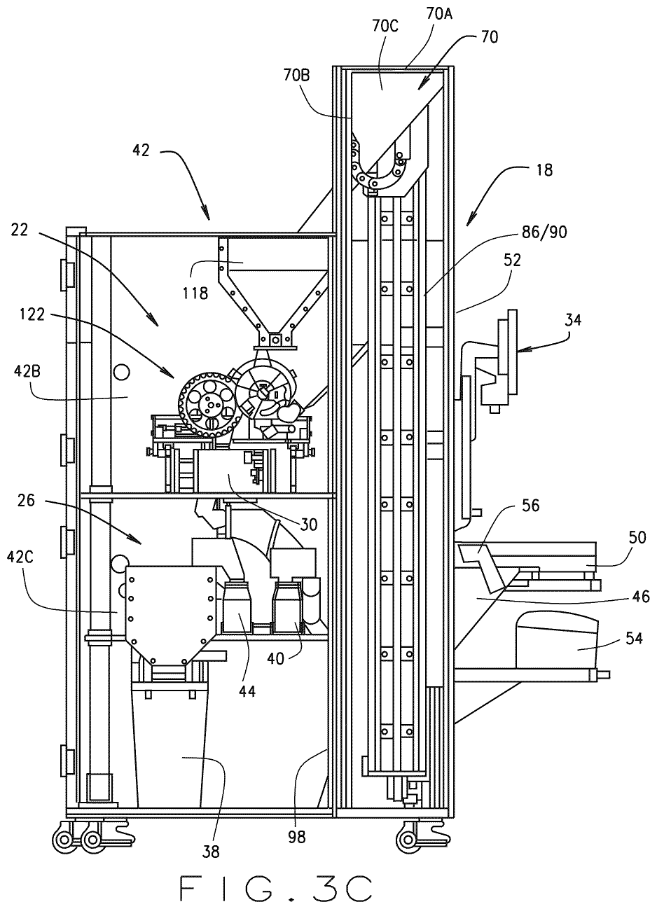

Referring now to FIGS. 1, 2B, 3A, 3B and 3C the elevator subsystem 18 comprises the elevator hopper 70 mounted to a conveyor 86 that is structured and operable to bidirectionally move, transport or convey the elevator hopper 70 between a lower or loading position (shown in FIGS. 2B, 3A and 3B) and an upper or offloading position (shown in FIG. 3C). In various embodiments, the elevator subsystem 18 is disposed within the elevator subsystem cabinet 42A. The elevator hopper 70 generally has a funnel or chute shape having an open top 70A, a back wall 70B and one or more sidewall 70C that extend from the back wall 70B to define an interior space of the elevator hopper 70. The conveyor 86 can be any system, apparatus or mechanism that is structured and operable to bidirectionally move, transport or convey the elevator hopper 70 between the lower loading position and an upper offloading position. For example, in various embodiments the conveyor 86 can comprise one or more track 90 to which the elevator hopper 70 is movably mounted and a linear actuator 94 that is structured and operable to bidirectionally move, transport or convey the elevator hopper 70 up and down along the track(s) 0 between the loading and offloading positions.

As described above, the elevator hopper 70 includes an open top 70A, a back wall 70B and one or more sidewall 70C. In various embodiments, the elevator hopper 70 is mounted to the conveyor 86 such that a plane of the back wall 70B is disposed substantially parallel with a plane of an interstitial housing wall 98. The interstitial housing wall 98 is a common wall of the housing 42 that provides an inner sidewall of the elevator subsystem cabinet 42A that is opposite the outer sidewall 52 of the housing/elevator cabinet 42/42A. Additionally, the elevator hopper 70 is mounted to the conveyor 86 such that such that the elevator hopper back wall 70B is in close proximity to the interstitial housing wall 98 (e.g., approximately ⅛ to ½ of an inch between the elevator hopper back wall 70B and the interstitial housing wall 98). Moreover, the conveyor 86 is mounted within the elevator subsystem cabinet such that the elevator hopper back wall 70B will remain in such close proximity to the interstitial housing wall 98 as the conveyor 86 selectably and controllably moves (as controlled by the system controller 34) the elevator hopper 70 back-and-forth between the loading position and the offloading position). As best shown in FIG. 2B, the back wall 70B of the elevator hopper 70 includes a dump hatch or opening 102. The back wall 70B additionally has a dump hatch door 106 mounted thereto that is selectably and controllably moved (as controlled by the system controller 34), via a dump hatch door actuator 110 between a Closed position and an Open position. When the dump hatch door 106 is disposed in the Closed position, small objects disposed within the interior space of the elevator hopper 70 are retained within the interior space of the elevator hopper 70. When the dump hatch door 106 is disposed in the Open position, small objects disposed within the interior space of the elevator hopper 70 are allowed to fall (via gravitation force) out of the elevator hopper interior space and through an offload port or aperture 112 formed in the interstitial wall 98 near the top of the elevator subsystem cabinet 42A and above a singulator hopper 118 of singulating and data collection subsystem 22 disposed in the singulating and data collection subsystem cabinet 42B.

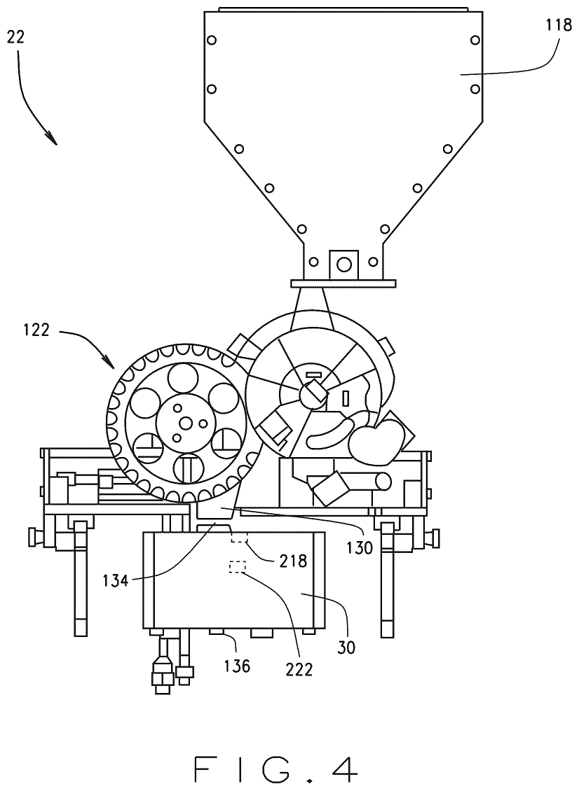

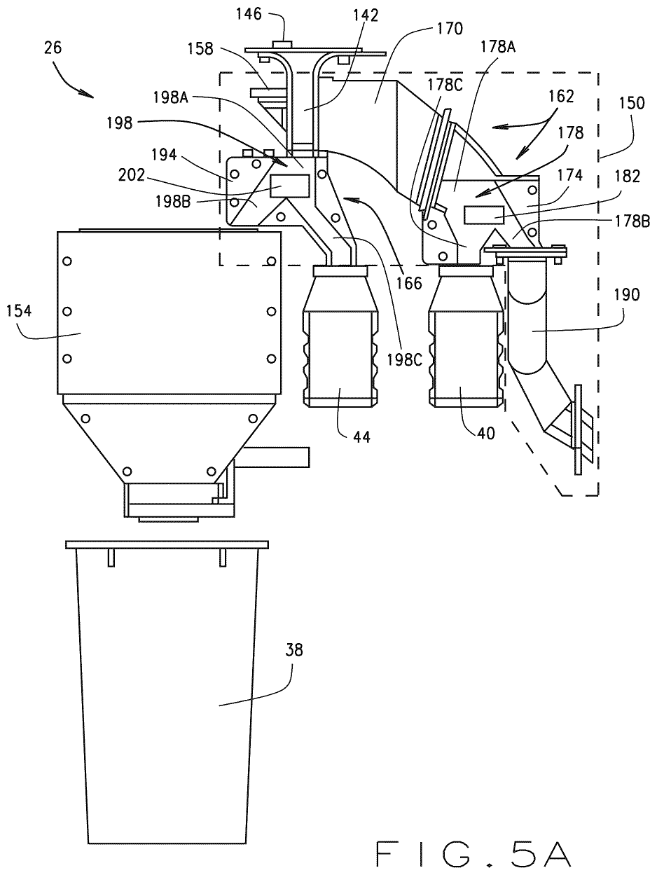

Referring now to FIGS. 1, 3B, 3C and 4, singulating and data collection subsystem 22 generally comprises the singulator hopper 118, a small object singulator 122 and the magnetic resonance imaging (MRI) device 30. The singulator hopper 118 is structured and operable to receive small object from the elevator hopper 70 (as described further below) a to feed the small object into the singulator 122. The singulator 122 is structured and operable to parse, or separate (e.g., singulate) individual small objects one-by-one from the plurality of seeds in the singulator hopper 118. The singulator 122 is further structured and operable to selectably and controllably dispense or feed each singulated small object, one-by-one, into the MRI device 30. Particularly, the singulator 122 singulates the small objects from the plurality of small objects in the singulator hopper 118 and dispenses each singulated small object, via a singulator outlet port 130, into an MRI device inlet funnel 134. The MRI device 30 is structured and operable to receive each singulated small object (e.g., receive each individual small object one-by-one), via the MRI device inlet funnel 134, and allow each singulated small object to free-fall via gravity through the MRI device 30 and exit the MRI device 30 through an outlet port 136 of the MRI device 30. As each small object free-falls through the MRI device 30 (e.g., travels through the MRI device 30 unimpaired and unimpeded, strictly due to the gravitational forces) during which time the MRI device, in real time, collects various data, such as the total mass and the oil content and/or the moisture content of each individual small object (e.g., oil and/or moisture mass data for each individual subject batch small object). The data is sent, in real time, to the system controller 34.

The system controller 34 analyzes, via execution of the system control and oil/moisture content analysis software, the data for each individual small object, in real time as each individual small objects falls through the MRI device 30, to determine whether each individual small object has a target oil and/or moisture content. As used herein, the target oil and/or moisture content will be understood to mean an oil and/or moisture content that is within a predetermined target range (e.g., greater than a predetermined lower threshold and less than a predetermined upper threshold). Subsequently, as described further below: 1) if the small objects are undergoing first-pass parsing, based on whether each respective individual small object has a target oil and/or moisture content, the system controller 34, via execution of the system control and oil/moisture content analysis software, controls operation of the parsing system 26 to in real time direct each respective individual small object to either the discard bin 38 or back to the elevator hopper 70 for second-pass analysis; or 2) if the small objects are undergoing second-pass analysis parsing, based on whether each respective individual small object has a target oil and/or moisture content, the system controller 34, via execution of the system control and oil/moisture content analysis software, controls operation of the parsing system 26 to in real time direct each respective individual small object to either the affirmatively identified small object container 40 or the tentatively identified small object container 44.

During operation of the MRI device 30, as each small object free-falls through the MRI device 30 via the force of gravity, a magnetic field generated by one or more electromagnet within the MRI device 30 is exerted on each respective small object. Generally, the magnetic field causes the protons of each respective small object to align parallel to the direction of the magnetic field. Subsequently, as each small object continues to free-fall through the MRI device 30, an RF probe within the MRI device 30 generates one or more pulses and receives an echo from each pulse. Each pulse disrupts, or disturbs, the proton alignment in each small object, whereby the amount of proton disruption is identified in the echo received from each pulse. The central control system 34, via execution of the system control and oil/moisture content analysis software, utilizes the amount of proton disruption from each echo to generate data indicative of the mass of the total mass of each respective small object and the oil and/or moisture content in each respective small object, sometimes referred to herein as the total mass data and the oil and/or moisture mass data. In various embodiments, the MRI device 30 can additionally include one or more sensor that is/are structured and operable to sense when each respective small object enters the MRI device 30 and when each respective small object exits the MRI device 30, and thereby determine the time it took for each respective small object to free-fall through the MRI device 30, and/or the speed and/or the velocity and/or the acceleration of each respective small object as it free-fell through the MRI device 30. The time and/or speed and/or velocity and/or acceleration data can be utilized during execution of the system control and oil/moisture content analysis software to determine the total mass data and the oil and/or moisture mass data, or other desired data, of each respective small object. The total mass data and the oil and/or moisture mass data (and any other desired data) for each respective small object is stored in memory (e.g., a database or table) of the system controller 34.

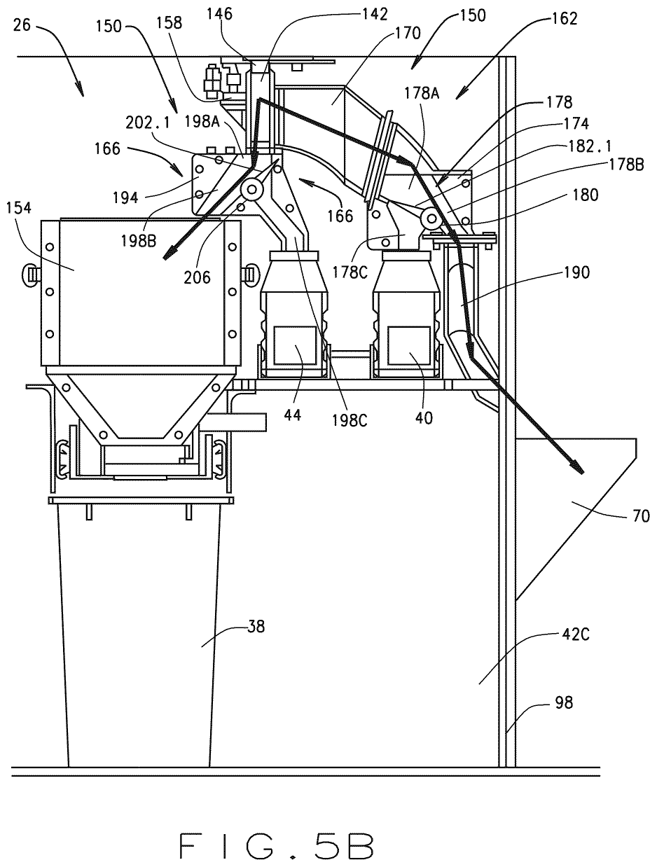

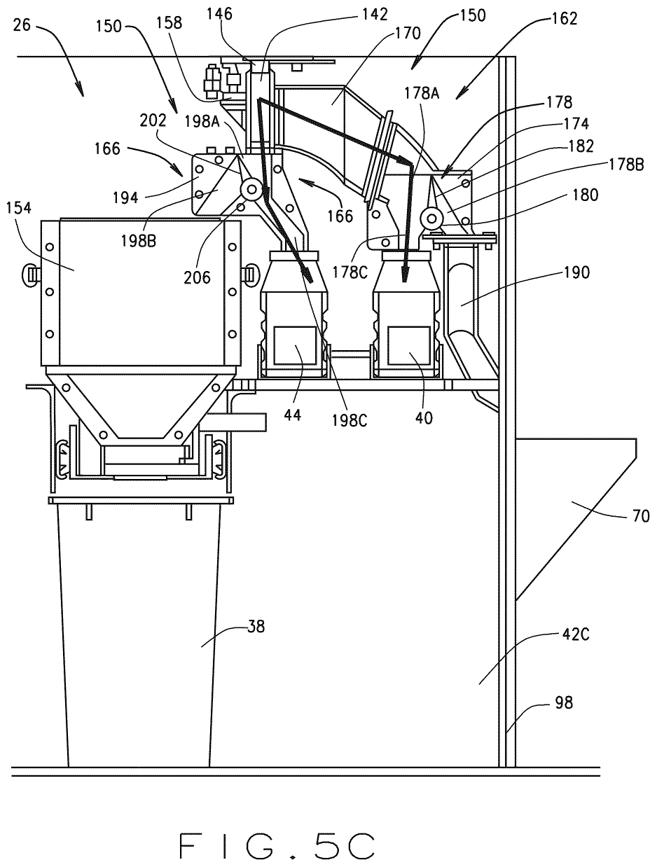

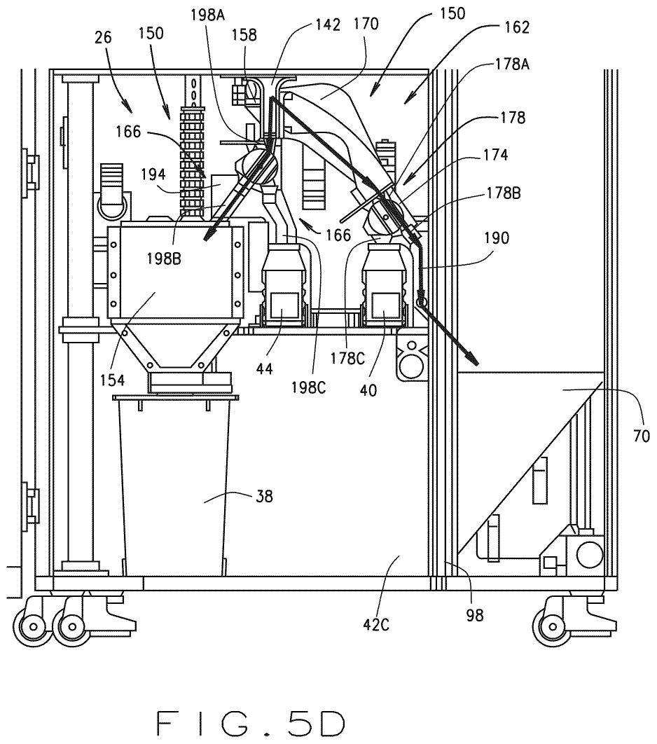

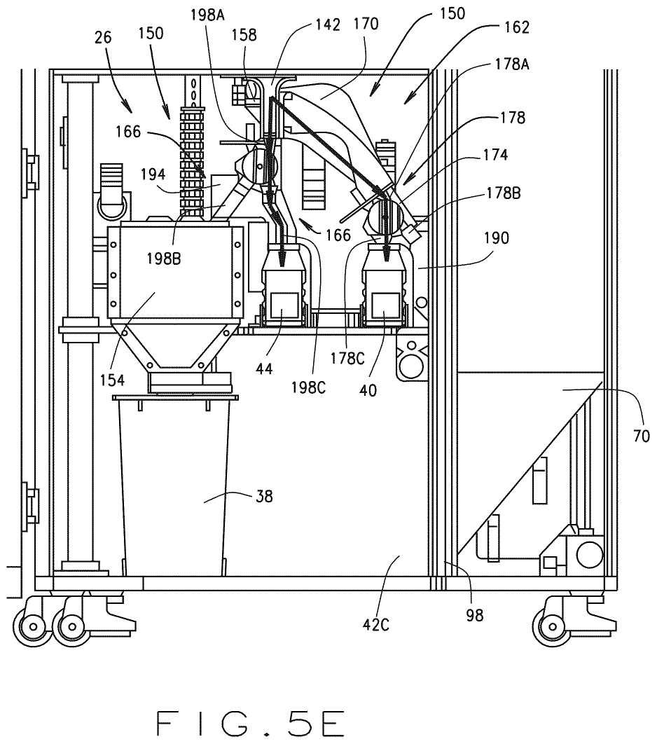

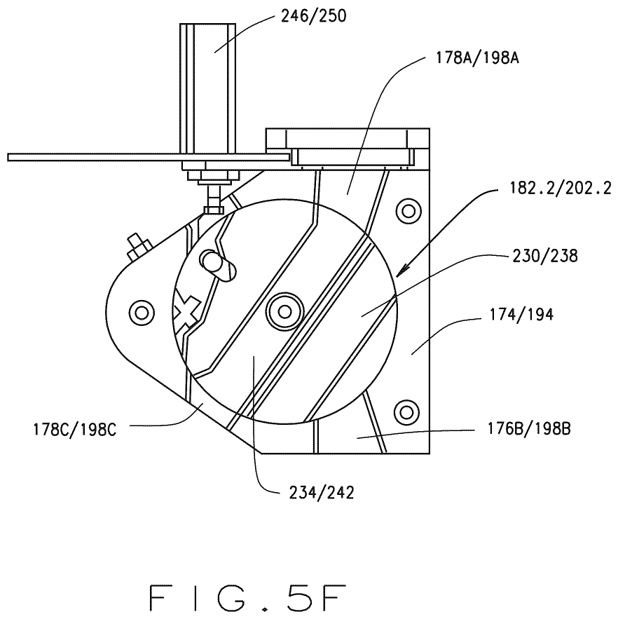

Referring now to FIG. 5A, the parsing subsystem 26 generally comprises a parsing subsystem trigger sensor 146, a diverter assembly 150, the affirmatively identified small object container 40, the tentatively identified small object container 44, a discard bin hopper 154, and the discard bin 38. In various embodiments, the parsing subsystem trigger sensor 146 senses when a small object exits the MRI device 30. In various embodiments, the diverter assembly 150 comprises a hollow inlet tube 142, a blow-off device 158 mounted to a first side of the inlet tube 142 and in fluid communication with in internal lumen of the inlet tube 142 via an opening in the first side of the inlet tube 142 (not shown), a target content diverter subassembly 162 mounted to an opposing second side of the inlet tube 142 and in fluid communication with the internal lumen of the inlet tube 142 via an opening in the second side of the inlet tube 142 (not shown), a non-target content diverter subassembly 166 mounted to a bottom of the parsing subsystem inlet tube 142 and in fluid communication with the internal lumen of the parsing subsystem inlet tube 142, and a second-pass return tube 190 connected to and in fluid communication with the target content diverter subassembly 162.

The target content diverter subassembly 162 comprises a receiving conduit 170 that is mounted to the second side of the parsing subsystem inlet tube 142 and extends between the inlet tube 142 and a first Y-channel box 174 of the target content diverter subassembly 162. The first Y-channel box 174 comprises a first Y-shaped hollow channel 178 that is fluidly connected to the receiving conduit 170. Particularly, the first Y-shaped hollow channel 178 includes a leg 178A fluidly connected to an internal lumen of the receiving conduit 170 and a first arm 178B and second arm 178C that are fluidly connected to the leg 178A and extend from the leg 178A in different directions. The first Y-channel box 174 additionally comprises a target diverting device 182 that is disposed between the first and second arms 178B and 178C and is structured and operable to selectively direct small objects falling through the leg 178A into one of the first and second arms 178B and 178C, as controlled by the system controller 34. The non-target content diverter subassembly 166 comprises a second Y-channel box 194 connected to bottom of the parsing subsystem inlet tube 142 and in fluid communication with the internal lumen of the parsing subsystem inlet tube 142. The second Y-channel box 194 comprises a second Y-shaped hollow channel 198 that includes a leg 198A fluidly connected to the internal lumen of the parsing subsystem inlet tube 142 and a first arm 198B and second arm 198C that are fluidly connected to the leg 198A and extend from the leg 198A in different directions. The second Y-channel box 194 additionally comprises a non-target diverting device 202 that is disposed between the first and second arms 198B and 198C and is structured and operable to selectively direct small objects falling through the leg 198A into one of the first and second arms 198B and 198C, as controlled by the system controller 34.

Referring now to FIGS. 5B, 50, 5D, 5E and 5F, the target diverting device 182 and the non-target diverting device 202 can be any device structured and operable to selectively direct small objects falling through the respective leg 178A or 198A into one of the respective first and second arms 178B or 198B and 178C or 198C.

For example, with reference to FIGS. 5B and 5C, in various embodiments the target diverting device 182 and the non-target diverting device 202 can respectively comprise a target diverting flap 182.1 and a non-target diverting flap 202.1. In such embodiments, the first Y-channel box 174 additionally comprises the target diverting flap 182.1 that is pivotally disposed between the first and second arms 178B and 178C and is connected to a target flap actuator 180 that is controlled by the system controller 34 to selectably move the target diverting flap 182.1 between first position (shown in FIG. 5B) and a second position (shown in FIG. 5C). As described below, when in the first position, the target diverting flap 182.1 will direct small objects into the second-pass return tube 190, and when in the second position, the target diverting flap 182.1 will direct small objects into the affirmatively identified small object container 40. Additionally, in such embodiments, the second Y-channel box 194 comprises the non-target diverting flap 202.1 that is pivotally disposed between the first and second arms 198B and 198C and is connected to a non-target flap actuator 206 that is controlled by the system controller 34 to selectably move the non-target diverting flap 202.1 between a first position (shown in FIG. 5B) and a second position (shown in FIG. 5C). As described below, when in the first position, the non-target diverting flap 202.1 will direct small objects into the discard bin hopper 154, and when in the second position, the non-target diverting flap 202.1 will direct small objects into the tentatively identified small object container 40.

Alternatively, with reference to FIGS. 5D, 5E and 5F, in various embodiments the target diverting device 182 and the non-target diverting device 202 can respectively comprise a target diverting disk 182.2 and a non-target diverting flap 202.2 (both exemplarily illustrated in FIG. 5C). The target diverting disk 182.2 comprises a first hollow conduit 230 extending therethrough and a second hollow conduit 234 extending therethrough. Similarly, the non-target diverting disk 202.2 comprises a first hollow conduit 238 extending therethrough and a second hollow conduit 242 extending therethrough. In such embodiments, the first Y-channel box 174 additionally comprises the target diverting disk 182.2 that is pivotally or rotationally disposed adjacent the first and second arms 178B and 178C and is connected to a target disk actuator 246 that is controlled by the system controller 34 to selectably rotate the target diverting disk 182.2 between first position (shown in FIG. 5D) and a second position (shown in FIG. 5E). As described below, when in the first position, the target diverting disk 182.2 will be oriented such that the first conduit 230 is aligned between the leg 178A and the first arm 178B of the first Y-channel box 178 to thereby direct small objects into the second-pass return tube 190. Additionally, when in the second position, the target diverting disk 182.2 will be oriented such that the second conduit 234 is aligned between the leg 178A and the second arm 178C of the first Y-channel box 178 to thereby direct small objects into the affirmatively identified small object container 40.

Additionally, in such embodiments, the second Y-channel box 194 comprises the non-target diverting disk 202.1 that is pivotally or rotationally disposed adjacent the first and second arms 198B and 198C and is connected to a non-target disk actuator 250 that is controlled by the system controller 34 to selectably rotate the non-target diverting disk 202.2 between a first position (shown in FIG. 5D) and a second position (shown in FIG. 5E). As described below, when in the first position, the non-target diverting disk 202.2 will be oriented such that the second conduit 242 is aligned between the leg 198A and the second arm 198C of the second Y-channel box 198 to thereby direct small objects into the discard bin hopper 154. Additionally, when in the second position the non-target diverting disk 202.2 will be oriented such that the first conduit 228 is aligned between the leg 198A and the first arm 198B of the second Y-channel box 198 to thereby direct small objects into the tentatively identified small object container 40.

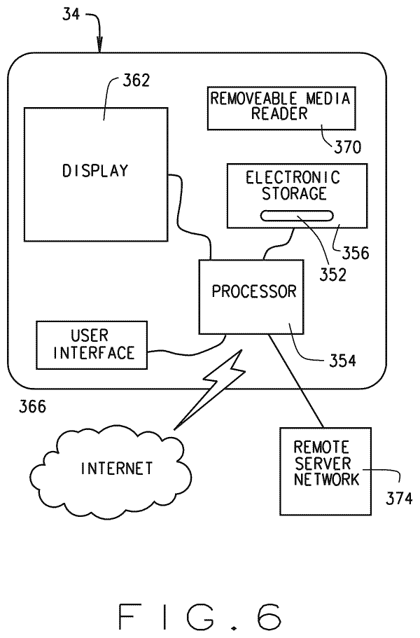

Referring now to FIG. 6, as described above, the system controller 34 controls all operations of the high throughput small object sorting system 10. Particularly, the system controller 34 controls and coordinates all operations of all components, computers, controllers, programmable circuitry, electrical modules, etc., of the input/output console 14, the elevator subsystem 18, the singulating and data collection subsystem 22, and the parsing subsystem 26 by execution of system control and oil/moisture content analysis software (identified in FIG. 6 by reference number 352). The system controller 34 is a computer-based system that can includes at least one processor 354 suitable to execute the system control and oil/moisture content analysis software 352, and/or other programs, algorithms and code that control all automated functions and operations of the sorting system 10, as described herein. The system controller 34 can additionally include at least one electronic storage device 356 that comprises a computer readable medium, e.g., non-transitory, tangible, computer-readable medium, such as a hard drive, erasable programmable read-only memory (EPROM), electronically erasable programmable read-only memory (EEPROM), read-write memory (RWM), etc. Other, non-limiting examples of the non-transitory, tangible, computer-readable medium are nonvolatile memory, magnetic storage, and optical storage. Generally, the computer readable memory can be any electronic data storage device or module for storing such things as the system control and oil/moisture content analysis software, programs, algorithms, code, digital information, data, look-up tables, spreadsheets and/or databases, etc., used and executed during operation of the sorting system 10, as described herein.

Furthermore, the system controller 34 includes at least one display 362 for displaying such things as information, data and/or graphical representations, and at least one user interface device 366, such as a keyboard, mouse, stylus, and/or an interactive touch-screen on the display 362. In various embodiments, system controller 34 can include a removable media reader 370 for reading information and data from and/or writing information and data to removable electronic storage media such as flash drives or any other computer readable removable and portable electronic storage media. In various embodiments the removable media reader 370 can be an I/O port utilized to read external or peripheral memory devices such as flash drives or external hard drives.

In various embodiments, system controller 34 can be communicatively connectable to a remote server network 374, e.g., a local area network (LAN), via a wired or wireless link. Accordingly, the system controller 34 can communicate with the remote server network 374 to upload and/or download data, information, algorithms, software programs, and/or receive operational commands. Additionally, in various embodiments, the system controller 34 can be structured and operable to access the Internet to upload and/or download data, information, algorithms, software programs, etc., to and from Internet sites and network servers. In various embodiments, the system control and oil/moisture content analysis software, programs, algorithms, and/or code executed by the processor(s) 354 to control the operations of the sorting system can be top-level system control software that not only controls the discrete hardware functionality of the input/output console 14, the elevator subsystem 18, the singulating and data collection subsystem 22 and the parsing subsystem 26, but also prompts an operator for various inputs via the display 362. As described above, in various embodiments, the system controller 34 can be an all-in-one touch screen computer.

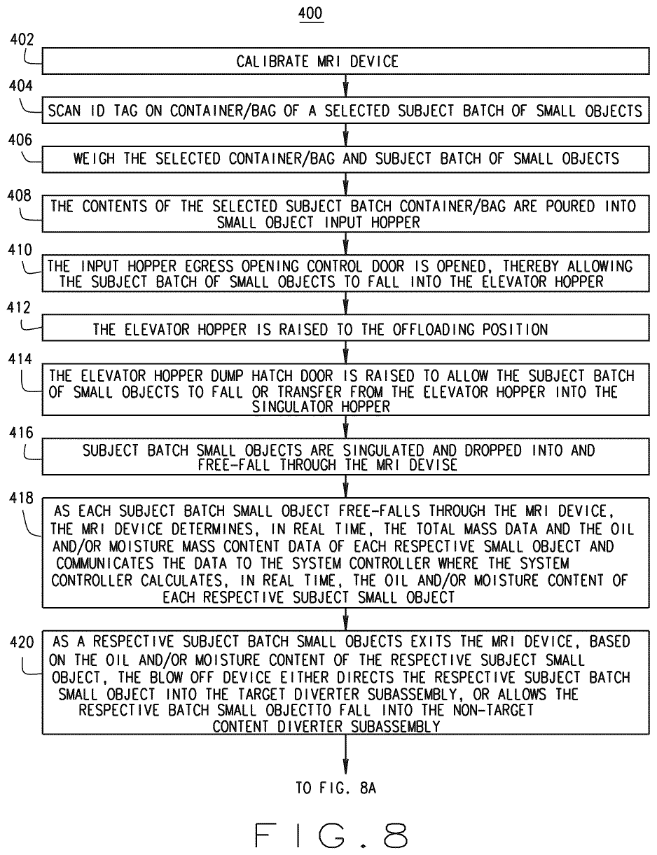

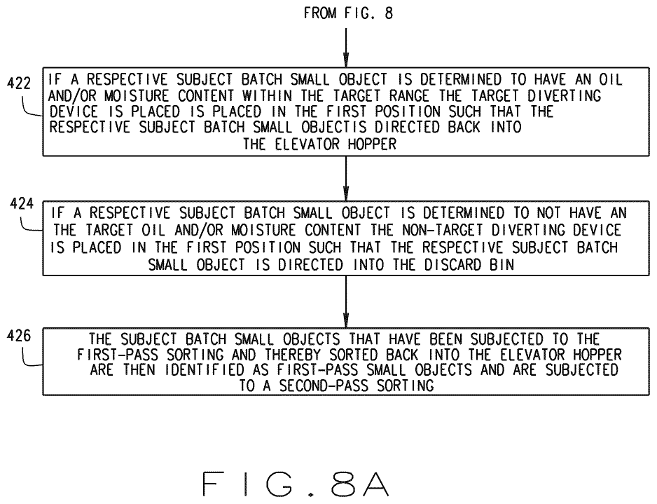

FIGS. 8 and 8A provide a flow chart 400 exemplarily illustrating a first-pass analysis and sorting operation of the high throughput small object sorting system 10 in accordance with various embodiments of the present disclosure. Generally, the high throughput small object sorting system 10 is structured and operable to, via execution of the system control and oil/moisture content analysis software, analyze data generated and collected by the sorting system 10 to identify and separate small objects based on oil and/or moisture content, at a high rate of speed. More particularly, high throughput small object sorting system 10 is structured and operable to execute a first-pass analysis sorting operation and a second-pass analysis and sorting operation to sort a subject batch of small objects into a target batch of small objects that affirmatively have a target oil and/or moisture content (e.g., an oil and/or moisture content that is within a predetermined target range), a non-target batch of small objects that tentatively have a target oil and/or moisture content, and a discarded batch of small objects that do not have that have a target oil and/or moisture content.

The small objects can be any small object comprising oil and/or moisture, or other molecular and manufactured composition that is detectable by MRI scanning. For example, in various embodiments, the high throughput small object sorting system 10 is structured and operable to sort a subject batch of seeds (e.g., soybean or corn seeds) into a target batch of seeds that affirmatively have a target oil and/or moisture content (e.g., an oil and/or moisture content that is within the predetermined target range that identifies the seeds as haploid seeds), a non-target batch of small objects that tentatively have a target oil and/or moisture content (e.g., an oil and/or moisture content that may or may not be within the target range that identifies the seeds as tentative or possible haploid seeds), and a discarded batch of seeds that do not have that have a target oil and/or moisture content (e.g., seeds that do not have an oil and/or moisture content that within the target range that identifies the seeds as diploid seeds).

Referring particularly to FIGS. 8 and 8A, as described above, to sort a subject batch of small objects, the sorting system 10 executes a first-pass analysis and sorting operation and then subsequently executes a second-pass analysis and sorting operation. In various instances, to initiate the first-pass analysis and sorting operation, the MRI device 30 is calibrated, as indicated at 402. In various other instances the MRI device 30 calibration can be skipped or performed at a different time. The calibration can be accomplished using any known method. For example, in various embodiments, this can be done by placing a precise oil and/or moisture filled capsule of some sort inside the MRI device 30, and then calibrate the MRI device 30 to that know oil and/or moisture amount. Once the MRI device 30 has been calibrated, the ID tag or label 210 affixed to a small object container or bag 214 (see FIG. 7) having a subject batch of small objects disposed therein is scanned utilizing the ID tag reader 56, as illustrated in 404. The ID tag 210 can be any type of machine-readable tag or label that provides various information regarding the batch of small objects disposed within the container/bag 214. For example, the ID tag 210 can be a barcode tag, QR code tag, RFID tag, etc., that provides information regarding the number and/or the type and/or the grouping and/or one or more trait of small objects disposed within the respective subject batch container/bag 214. Thereafter, the subject batch container/bag 214 having the subject batch of small objects disposed therein is weighed utilizing the scale 50, as indicated at 406. The weight and/or mass of the subject batch container/bag 214 having the subject batch of small objects disposed therein is then entered and stored in the memory (e.g., a database or table) of the system controller 34 either manually, via the user interface 366 are automatically, via a communication connection (wired or wireless) between the scale 50 and the system controller 34.

Next, during the first-pass analysis and sorting operation, the contents of the selected subject batch container/bag 214 (i.e., all the small objects disposed within the subject batch container/bag 214) are poured into the small object input hopper 46, as indicated at 408. Subsequently, the system controller 34 opens the input hopper egress opening control door 62, via controlled operation of the egress opening control door actuator 66, thereby allowing the subject batch of small objects to fall or transfer from the small object input hopper 46, through the input hopper egress opening 58, into the elevator hopper 70, as indicated at 410. As illustrated in FIG. 3B, when the subject batch of small objects are transferred from the unput hopper 46 to the elevator hopper 70, the elevator hopper 70 is positioned at the bottom of the elevator subsystem cabinet 42A in the loading position and the elevator hopper dump hatch door 106 is in the Closed position. The elevator hopper 70, having the subject batch of small objects disposed therein is then raised, via the conveyor 86 as controlled by the system controller 34, to the top of the elevator subsystem cabinet 42 into the offloading position, as indicated at 412. Next, the system controller 34 controls operation of the elevator hopper dump hatch door actuator 110 to raise the elevator hopper dump hatch door from the Closed position to the Open position, thereby allowing the subject batch of small objects to fall or transfer from the elevator hopper 70 into the singulator hopper 118, as indicated at 414. It should be noted that it is envisioned that the elevator subsystem 18 as described herein is only exemplary, and any other suitable method, means of system of conveying the subject batch of small objects from the input hopper 46 to the offload port 112 and depositing them into the singulator hopper 118 is within the scope of the present disclosure.

Next, the subject batch of small objects are fed from the singulator hopper 118 into the singulator 122 where, as described above, the subject batch of small objects are parsed one-by-one from the plurality of small objects in the singulator hopper 118 (e.g., the subject batch of small objects are singulated) and dispensed one-by-one out the singulator output port 130 and dropped into the MRI inlet funnel 134, as indicated at 416.

The singular 122 can be any device, apparatus, mechanism or system that is structured and operable to parse one-by-one the plurality small objects in the singulator hopper 118 and dispense them one-by-one into the MRI inlet funnel 134 and remain within the scope of the present disclosure. For example, in various embodiments, the singulator 122 can be a singulating and counting module as disclosed and described in U.S. Pat. No. 8,925,762, issued Jan. 6, 2015 and titled High Speed Counter, and/or a seed feeder assembly as disclosed and described in U.S. Pat. No. 9,658,176, issued May 23, 2017 and titled High-Throughput Sorting Of Small Objects Via Oil And/Or Moisture Content Using Low-Field Nuclear Magnetic Resonance, the disclosures of which are incorporated herein by reference in their entirety.

As each subject batch small object is dropped one-by-one into the MRI device 30 and free-falls through the MRI device 30, the MRI device 30, as described above, determines, in real time, the total mass data and the oil and/or moisture mass content data of each respective subject batch small object and communicates this data to the system controller 34 where, via execution of the system control and oil/moisture content analysis software, the system controller 34 calculates, in real time as each respective small object free-falls through the MRI device 30, the oil and/or moisture content of each respective subject batch small object, as indicated at 418.

In various embodiments, the MRI device 30 comprises an upper sensor 218 disposed adjacent the MRI inlet funnel 134 and a lower sensor 222 disposed in the center of the MRI device 30. The MRI upper sensor 218 senses when each small object enters the MRI device 30, which starts a timer, and the MRI lower sensor 222 triggers the MRI device 30 to acquire data and also stops the timer. Furthermore, upon sensing a small object entering the MRI device 30, the MRI lower sensor 222 is structured and operable to trigger the MRI device to determine the total mass data and the oil and/or moisture mass data for each respective small object. Additionally, upon sensing a small object is exiting the MRI device 30, the lower MRI sensor 222 is structured and operable to trigger computation by the system controller 34 of the oil and/or moisture content (e.g., the oil and/or moisture percentage) of each respective small object, via execution of the system control and oil/moisture content analysis software. Execution of the system control and oil/moisture content analysis software to calculate the oil and/or moisture content of each respective small object, in real time as each respective small object free-falls through the MRI device 30, can comprise execution of any sorting algorithm suitable for determining whether the oil and/or moisture content of each respective small object (e.g., the percentage of oil and/or moisture mass in each respective small object) falls with within a predetermined range. In various instances, the time difference between the MRI upper sensor 218 sensing each respective small object and the lower sensor 222 sensing each respective small object can be utilized by the system controller 34 to determine the speed and/or velocity of each respective small object as it free-fell through the MRI device 30.

Upon sensing a small object exiting the MRI device 30, via the MRI lower sensor 22, operation of the parsing subsystem 26 is triggered, whereby, via control of the system controller 34, the parsing subsystem 26 directs each respective small object to a desired location, e.g., to either the discard bin 38, or the affirmatively identified small object container 40, or the tentatively identified small object container 44, or the elevator hopper 70, based on the determined oil and/or moisture content of each respective small object.

Particularly, as illustrated in FIG. 5B, as a respective singulated subject batch small object exits the MRI device 30, the respective subject batch small object free-falls into the parsing system inlet tube 142 and begins to pass the blow-off device 158 where, based on the oil and/or moisture content of each respective small object, the blow-off device 158 either directs the respective subject batch small object into the receiving conduit 170 of the target diverter subassembly 162, or allows the respective subject batch small object to pass the blow-off device 158 and fall into the second Y-channel box 194 of the non-target content diverter subassembly 166, as indicated at 420. Specifically, during first-pass analysis and sorting operation, the system controller 34 will place the target diverting device 182 (e.g., the target diverting flap 182.1 or the target diverting disk 182.2) in the first position and also place the non-target diverting device 202 (e.g., the non-target diverting flap 202.1 or the non-target diverting disk 202.2) in the first position. Therefore, if a respective subject batch small object is determined to have an oil and/or moisture content within the predetermined target range and is directed into the receiving conduit 170 of the target diverter subassembly 162. The target diverting device 182 (e.g., the target diverting flap 182.1 or the target diverting disk 182.2) being in the first position (FIG. 5B) will direct the respective subject batch small object through the first arm 178B of the first Y-shaped hollow channel 178 of first Y-channel box 174 and into the second-pass return tube 190, which in turn directs the respective subject batch small object through a second pass port 226 (FIG. 1) in the interstitial wall 98 of the housing 42 and back into the elevator hopper 70, as indicated at 422. However, if a respective subject batch small object is determined to not have the target oil and/or moisture content and is directed or allowed to fall into the second Y-channel box 194 of the non-target content diverter subassembly 166. The non-target diverting device 202 (e.g., the non-target diverting flap 202.1 or the non-target diverting disk 202.2) being in the first position (FIG. 5B) will direct the respective subject batch small object is directed through the first arm 198B of the second Y-shaped hollow channel 198 of first Y-channel box 194 and into the discard bin hopper 154, which in turn directs the respective subject batch small object into the discard bin 38, as indicated at 424.

The subject batch of small objects that has been subjected to the first-pass analysis and sorting and thereby sorted back into the elevator hopper 70 are then identified as first-pass small objects, are collectively referred to as the first-pass batch of small objects and are subjected to a second-pass sorting, as indicated at 426.

The blow-off device 158 can be any device structured and operable to direct each respective small object into either the receiving conduit 170 of the target diverter subassembly 162, or into the second Y-channel box 194 of the non-target content diverter subassembly 166. For example, in various embodiments, the blow-off device 158 can be an air nozzle or port that is fluidly connected to a compressed air supply of the (not shown) of the sorting system 10. In such embodiments, the air nozzle blow-off device 158 can be: 1) activated by the system controller 34 to release a puff of air that directs a respective free-falling small object that has been determined to have an oil and/or moisture content within the target range into the receiving conduit 170 of the target diverter subassembly 162; and 2) prevented from being activated by the system controller 34 to allow a respective free-falling small object that has been determined to have an oil and/or moisture content that is outside of the target range to fall into the second Y-channel box 194 of the non-target content diverter subassembly 166. Alternatively, the blow-off device 158 can be a mechanical device that, as controlled by the system controller 34:1) directs a respective free-falling small object that has been determined to have an oil and/or moisture content within the target range into the receiving conduit 170 of the target diverter subassembly 162; and 2) directs or allows a respective free-falling small object that has been determined to have an oil and/or moisture content that is outside of the target range to be directed into or fall into the second Y-channel box 194 of the non-target content diverter subassembly 166.

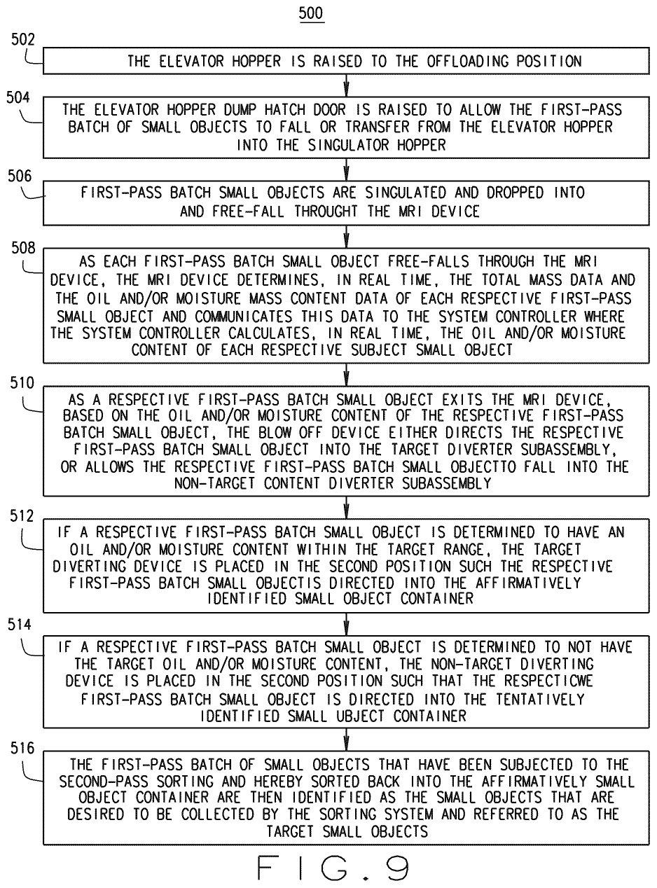

Referring particularly to FIG. 9, as described above, to sort a subject batch of small objects, the sorting system 10 executes a first-pass analysis and sorting operation and then subsequently executes a second-pass analysis and sorting operation. As described above, the first-pass analysis and sorting operation identifies small objects that have a target oil and/or moisture content (i.e., an oil and/or moisture content that is within the desired predetermined target range) and deposits such small objects back into the elevator hopper 70, and such small objects identified and referred to herein as first-pass small objects. As also described above, such first-pass small objects are then subjected to a second-pass sorting.

FIG. 9 provides a flow chart 500 exemplarily illustrating a second-pass analysis and sorting operation of the high throughput small object sorting system 10 in accordance with various embodiments of the present disclosure. As illustrated in FIG. 5C, when the first-pass batch small objects are deposited back into the elevator hopper 70, the elevator hopper 70 is positioned at the bottom of the elevator subsystem cabinet 42A in the loading position and the elevator hopper dump hatch door 106 is in the Closed position. During the second-pass analysis and sorting operation, the elevator hopper 70, having the first-pass batch of small objects disposed therein is then raised, via the conveyor 86 as controlled by the system controller 34, to the top of the elevator subsystem cabinet 42 into the offloading position, as indicated at 502. Next, the system controller 34 controls operation of the elevator hopper dump hatch door actuator 110 to raise the elevator hopper dump hatch door from the Closed position to the Open position, thereby allowing the first-pass batch of small objects to fall or transfer from the elevator hopper 70 into the singulator hopper 118, as indicated at 504. As described above, it should be noted that it is envisioned that the elevator subsystem 18 as described herein is only exemplary, and any other suitable method, means of system of conveying the first-pass batch of small objects from the second-pass port 226 to the offload port 112 and depositing them into the singulator hopper 118 is within the scope of the present disclosure.

Next, the first-pass batch of small objects are fed from the singulator hopper 118 into the singulator 122 where, as described above, the first-pass batch of small objects are parsed one-by-one from the plurality of small objects in the singulator hopper 118 (e.g., the first-pass batch of small objects are singulated) and dispensed one-by-one out the singulator output port 130 and dropped into the MRI inlet funnel 134, as indicated at 506. As each first-pass batch of small object is dropped one-by-one into the MRI device 30 and free-falls through the MRI device 30, the MRI device 30, as described above, determines, in real time, the total mass data and the oil and/or moisture mass content data of each respective first-pass batch small object and communicates this data to the system controller 34 where, via execution of the system control and oil/moisture content analysis software, the system controller 34 calculates, in real time as each respective small object free-falls through the MRI device 30, the oil and/or moisture content of each respective first-pass batch small object, as indicated at 508.

As illustrated in FIG. 50, as a respective singulated first-pass batch small object exits the MRI device 30, the respective first-pass batch small object free-falls into the parsing system inlet tube 142 and begins to pass the blow-off device 158 where, based on the oil and/or moisture content of each respective small object, the blow-off device 158 either directs the respective first-pass batch small object into the receiving conduit 170 of the target diverter subassembly 162, or allows the respective first-pass batch small object to pass the blow-off device 158 and fall into the second Y-channel box 194 of the non-target content diverter subassembly 166, as indicated at 510. Specifically, during second-pass analysis and sorting operation, the system controller 34, via the target actuator 186 will place the target diverting device 182 (e.g., the target diverting flap 182.1 or the target diverting disk 182.2) in the second position and also, via the non-target actuator 206, place the non-target diverting device 202 (e.g., the non-target diverting flap 202.1 or the non-target diverting disk 202.2) in the second position. Therefore, if a respective first-pass batch small object is determined to have an oil and/or moisture content within the target range and is directed into the receiving conduit 170 of the target diverter subassembly 162. The target diverting device 182 (e.g., the target diverting flap 182.1 or the target diverting disk 182.2) being in the second position (FIG. 5C) will direct the respective first-pass batch small object through the second arm 178C of the first Y-shaped hollow channel 178 of first Y-channel box 174 and into the affirmatively identified small object container 40, as indicated at 512. However, if a respective first-pass batch small object is determined to not have the target oil and/or moisture content and is directed or allowed to fall into the second Y-channel box 194 of the non-target content diverter subassembly 166. The non-target diverting device 202 (e.g., the non-target diverting flap 202.1 or the non-target diverting disk 202.2) being in the second position (FIG. 5C) directs the respective first-pass batch small object is directed into the tentatively identified small object container 44, as indicated at 514.

The first-pass batch of small objects that have been subjected to the second-pass sorting and thereby sorted into the affirmatively identified small object container 40 are then identified as the small objects that are desired to be collected by the sorting system 10 and referred to herein as the target small objects or collectively as the target batch of small objects, as indicated at 516.

As described above, in various embodiments the small objects can be seeds. In such embodiments, during the first-pass operation of the sorting system 10 wherein the subject batch of seeds are sorted, the sorting system 10: 1) identifies subject batch seeds having an oil and/or moisture content within the target range as possible haploids and sorts are directs such possible haploid seeds back to the elevator hopper 70 as described above; and 2) identifies subject batch seeds that have an oil and/or moisture content that outside the target range as diploids and sorts or directs the diploids to the discard bin 38, as described above. Subsequently, during the second-pass operation of the sorting system 10 wherein the first-pass batch of seeds are sorted, the sorting system 10: 1) identifies first-pass batch seeds having an oil and/or moisture content within the target range as affirmatively identified haploids and sorts are directs such affirmatively identified haploid seeds into the affirmatively identified small object container 40, as described above; and 2) identifies first-pass batch seeds that have an oil and/or moisture content that outside the target range as tentatively identified haploids and sorts or directs the tentatively identified haploids to the tentatively identified small object container 44, as described above

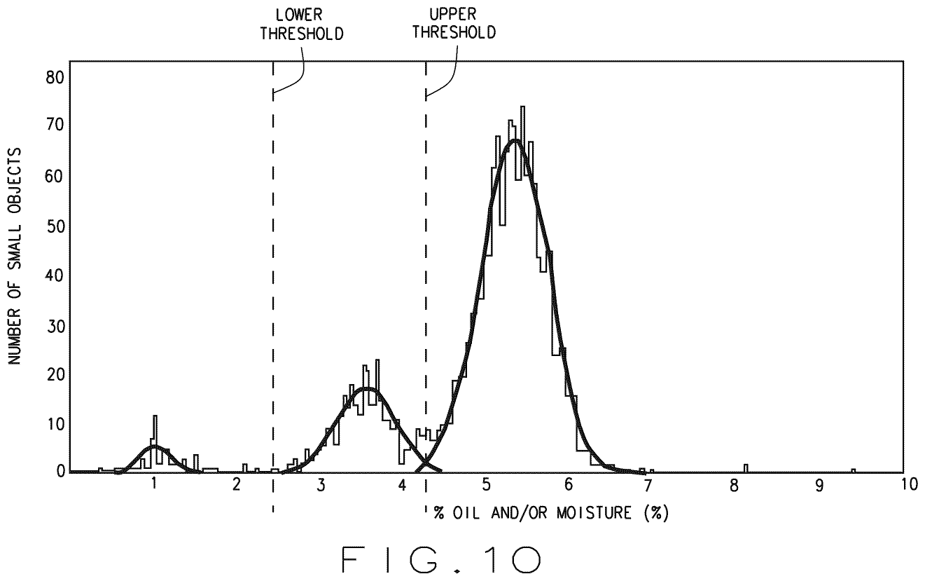

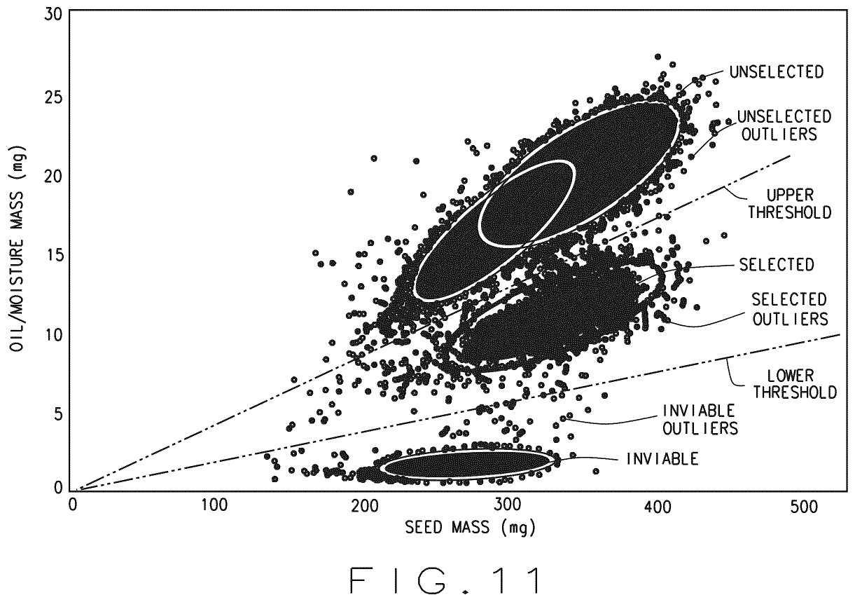

Referring now to FIGS. 10 and 11, as described above, execution of the system control and oil/moisture content analysis software to calculate the total mass and the oil and/or moisture mass content of each respective small object in real time as each respective small object free-falls through the MRI device 30 can comprise execution of any sorting algorithm suitable for determining whether the oil and/or moisture content of each respective small object (e.g., the percentage of oil and/or moisture mass in each respective small object) falls with within a predetermined range.

For example, as exemplarily illustrated in FIG. 10 in various embodiments, during the first-pass analysis and sorting operation of the subject batch of small objects (e.g., seeds) and/or the second-pass analysis and sorting operation of the first-pass batch of small objects (e.g., seeds) the system control and oil/moisture content analysis software can comprise a first sorting algorithm that plots the percent of oil and/or moisture (exemplarily illustrated as percent of oil) for each small object in the subject batch of small objects and/or the first-pass batch of small objects. More particularly, the small objects are evaluated and plotted by oil and/or moisture content in bell curves as 1D Gaussian fits, discarding any small object having an oil/moisture % above an upper threshold or value as determined by the curve fits, keeping small objects having an oil/moisture % between a lower threshold or value and the upper threshold or value, and discarding any small object having an oil/moisture % under lower threshold or value. For example, keeping small objects that have between 2% oil/moisture content (i.e., the lower threshold or value) and the upper threshold or value that is determined by the curve fits (in various instances determined based on the oil/moisture content of approximately the first 750 small objects). Small objects having an oil/moisture content above the upper threshold/value or below the lower threshold/value are discarded. For example, if the small objects are seeds, seeds with oil/moisture content below the lower threshold are assumed to be broken/damaged, embryo-less, or otherwise unable to germinate seeds). For example, in various instances the starting range for the small objects that are retained for second-pass analysis and sorting can be 2.0%-4.0% but can be changed as desired by a system operator. In various embodiments, the upper and lower thresholds can be determined by evaluating the data for a predetermined number of initial small objects dropped into the MRI device 30 (e.g., approximately the first 750 small objects) at a specified frequency. In various instances, both the starting point and frequency are changeable by the system operator. In various instances, a standard procedure can be the first curve fit is approximately 750 small objects with follow-ups every 1000 small objects after that until 6 curve fits are reached (e.g., approximately 5750 data points).

The exemplary bell curves shown in FIG. 10 are 1D Gaussian functions illustrating the distribution of oil/moisture percentage of each small object for the first-pass analysis and sorting operation and/or the second pass analysis and soring operation of the sorting system 10, based on the functions:

$$f ( x ) = \frac{1}{σ \sqrt{( 2 π )}} * {e}^{- {( x - μ )}^{2} / ( 2 {σ}^{2} )} \qquad ( 1 )$$

wherein μ=the mean of the distribution, σ=standard deviation, e=Euler's number, and x=integer;
and

$$σ = \sqrt{( \frac{\sum {( {x}_{i} - μ )}^{2}}{N} )} \qquad ( 2 )$$

wherein σ=population standard deviation, N=size of population, xᵢ=each value from the data set, and μ=population mean.

The example shown in FIG. 10 includes three peaks. The first curve (the curve centered around 1%) represents the small objects that have an oil and/or moisture content below the lower threshold and are discarded (e.g., if the small objects are seeds, they are discarded due to being inviable, as they won't germinate due to oil % being too low (embryo-less or broken/damaged kernels)). The second curve (the curve centered around 3.5%) is represents the selected low oil/moisture % small objects that are selected for second-pass sorting as described above (e.g., if the small objects are seeds, they are the seeds most likely to be haploids), and the third curve (the curve centered around 5.5%) represents the small objects that are discarded for having an oil/moisture content above the upper threshold (e.g., if the small objects are seeds, they are discarded due to high oil/moisture %, as they are most likely to be diploids).

Alternatively, as exemplarily illustrated in FIG. 11 in various embodiments, during the first-pass analysis and sorting operation of the subject batch of small objects (e.g., seeds) and/or the second-pass analysis and sorting of the first-pass batch of small objects (e.g., seeds) the system control and oil/moisture content analysis software can comprise a second sorting algorithm that plots the oil mass data or value for each respective small object of the first-pass batch of small objects, and separately plots the total mass data or value of each respective small object. For example, as exemplarily illustrated in FIG. 11 in various embodiments, during the first pass analysis and sorting and/or the second-pass sorting of the first-pass batch of small objects (e.g., seeds) the system control and oil/moisture content analysis software can comprise a second sorting algorithm that evaluates and plots using 2D Gaussian fits, wherein the second sorting algorithm sorts by evaluating the oil/moisture mass (mg) and total seed mass (mg) instead of oil/moisture percentage % (as described above with regard to FIG. 10). In various instances, the starting range for the small objects that are sorted into the affirmatively identified small object container 40 can be between 2.0%-4.0%, but can be changed as desired by the system operator. In various embodiments, the upper and lower thresholds can be determined by evaluating the data for a predetermined number of initial small objects dropped into the MRI device 30 (e.g., approximately the first 750 small objects) at a specified frequency. In various instances, both the starting point and frequency are changeable by the system operator. In various instances, a standard procedure can be the first curve fit is approximately 750 small objects with follow-ups every 1000 small objects after that until 6 curve fits are reached (e.g., approximately 5750 data points).

The exemplary plots shown in FIG. 11 are 2D Gaussian functions illustrating the distribution of oil/moisture mass and total mass for each small object during the first-pass analysis and sorting operation and/or the second-pass analysis and sorting operation of the sorting system 10, based on the function:

$$f ( x , y ) = ( \frac{1}{( 2 π * {σ}_{x} * {σ}_{y} )} ) * {e}^{- ( ( {( x - {μ}_{x} )}^{2} / ( 2 * {μ}_{x}^{2} ) ) + ( {( y - {μ}_{y} )}^{2} / ( 2 * {μ}_{y}^{2} ) ) )} \qquad ( 3 )$$

wherein x,y=coordinates in the 2D plane, μₓ,μ_{y}=center point of the Gaussian distribution along the x and y axis, respectively, and σₓ,σ_{y}=standard deviation along each axis.

The example shown in FIG. 11 includes two overlapping upper ellipses, one middle ellipse, and one lower ellipse. The lower ellipse represents the small objects that have an oil and/or moisture content below the lower threshold and are discarded (e.g., if the small objects are seeds, they are discarded due to being inviable, as they won't germinate due to oil % being too low (embryo-less or broken/damaged kernels)). The middle ellipse represents the small-objects that are sorted into the affirmatively identified small object container 40 as described above (e.g., if the small objects are seeds, they are the seeds most likely to be haploids), and the two overlapping upper ellipses represent the small objects that are discarded for having an oil/moisture content above the upper threshold (e.g., if the small objects are seeds, they are discarded due to high oil/moisture %, as they are most likely to be diploids).

The description herein is merely exemplary in nature and, thus, variations that do not depart from the gist of that which is described are intended to be within the scope of the teachings. Moreover, although the foregoing descriptions and the associated drawings describe example embodiments in the context of certain example combinations of elements and/or functions, it should be appreciated that different combinations of elements and/or functions can be provided by alternative embodiments without departing from the scope of the disclosure. Such variations and alternative combinations of elements and/or functions are not to be regarded as a departure from the spirit and scope of the teachings.

1. A high throughput small object sorting system, said system comprising:
a system controller structured and operable to control operation of the sorting system;
a singulating and data collection subsystem, the singulating and data collection subsystem comprising:
a magnetic resonance imaging (MRI) device;
a singulator hopper structured and operable to receive small objects from an elevator hopper; and
a singulator structured and operable to parse the small objects one-by-one from the singulator hopper and drop each small object into the MRI device such that each small object free-falls into and through the MRI device;
wherein, the MRI device is structured and operable to receive each small object from the singulator, determine total mass data and oil mass data of each small object received by the MRI device, and communicate the total mass and oil mass data for each small object received by the MRI device to the system controller as each small object free-falls through the MRI device; and
a parsing subsystem, the parsing subsystem comprising:
a diverter assembly structured and operable to direct each small object to one of a discard bin, an affirmatively identified small object container, a tentatively identified small object container, or the elevator hopper based on an oil content of each small object determined by the system controller utilizing the total mass and oil mass data.

2. The system of claim 1, wherein the parsing subsystem further comprises:
an inlet tube structured and operable to receive the small objects from the MRI device;
a target content diverter subassembly connected to the inlet tube;
a non-target content diverter subassembly connected to the inlet tube; and
a blow-off structured and operable to:
direct small objects that have a target oil content into the target content diverter subassembly; and
direct small objects that have non-target oil content into the non-target content diverter subassembly.

3. The system of claim 2, wherein the target content diverter subassembly comprises:
a receiving conduit structured and operable to receive small objects from the inlet tub that have the target oil content; and
a first Y-channel box connected to the receiving conduit, the first Y-channel box structured and operable to direct the small objects that have the target oil content into one of a second-pass return tube and the affirmatively identified small object container.

4. The system of claim 3, wherein the non-target content diverter subassembly comprises a second Y-channel box structured and operable to receive small objects from the inlet tube that have the non-target oil content, and to direct the small objects that have the non-target oil content into one of a discard bin hopper and the tentatively identified small object container.

5. A method for high throughput small object sorting, said method comprising:
during a first-pass sorting operation of a high throughput small object sorting system, one-by-one parsing subject small objects from a subject batch of small objects;
dropping each parsed subject small objects into an MRI device of the small object sorting system such that each parsed subject small objects free-falls through the MRI device;
collecting total mass data and an oil mass data for each parsed subject small object as each parsed subject small object free-falls through the MRI device;
in real time as each subject small object free-falls through the MRI device, calculating an oil content of each subject small object, via a system controller of the high throughput small object sorting system;
via execution of a sorting algorithm by a system controller, determining whether the oil content of each subject small object is one of within a first-pass target range and within a first-pass non-target range;
collecting the subject small objects that have an oil content within the first-pass target range to obtain a first-pass batch of small objects, and discarding the subject small objects that have an oil content with the first-pass non-target range;
during a second-pass sorting operation of a high throughput small object sorting system, one-by-one parsing first-pass small objects from the first-pass batch of small objects;
dropping each parsed first-pass small objects into the MRI device such that each parsed first-pass small objects free-falls through the MRI device;
collecting total mass data and an oil mass data for each parsed first-pass small object as each parsed first-pass small object free-falls through the MRI device;
in real time as each first-pass small object free-falls through the MRI device, calculating an oil content of each subject small object, via the system controller;
via execution of the sorting algorithm by a system controller, determining whether the oil content of each first-pass small object is one of within a second-pass target range and within a second-pass non-target range;
collecting the first-pass small objects that have an oil content within the second-pass target range in an affirmatively identified small object container, and collecting the first-pass small objects that have an oil content within the second-pass non-target range in a tentatively identified small object container.

6. The method of claim 5 further comprising:
depositing the subject batch of small objects into an elevator hopper of an elevator subsystem of the high throughput small object sorting system:
transporting the subject batch small objects to a singulator hopper of a singulating and data collection subsystem of the high throughput small object sorting system via a conveyor of the elevator subsystem; and
depositing the subject batch of small objects into the singulator hopper.

7. The method of claim 6, wherein one-by-one parsing the subject small objects from a subject batch of small objects comprises:
feeding the subject small objects into a singulator of the singulating and data collection subsystem; and
one-by-one parsing the subject small objects from a subject batch of small objects via operation of the singulator.

8. The method of claim 7, wherein dropping each parsed subject small objects into an MRI device such that each parsed subject small objects free-falls through the MRI device comprises dispensing each parsed subject small object from a singulator outlet port such that each parsed subject small object free-falls into an MRI device inlet funnel such that each parsed subject small object free-falls through the MRI device.

9. The method of claim 8, wherein collecting the subject small objects that have an oil content within the first-pass target range to obtain a first-pass batch of small objects comprises:
directing each subject small objects that has an oil content within the first-pass target range into a target content diverter subassembly of a diverter assembly of a parsing subsystem of the high throughput small object sorting system, via blow-off device of the diverter assembly; and
further directing each subject small object that has an oil content within the first-pass target range back into the elevator hopper via a target diverting device and a second-pass return tube of the target content diverter subassembly.

10. The method of claim 9 further comprising:
transporting the first-pass batch small objects to the singulator hopper; and
depositing the first-pass batch of small objects into the singulator hopper.

11. The method of claim 10, wherein collecting the first-pass small objects that have an oil content within the second-pass target range in the affirmatively identified small object container comprises:
directing each first-pass small objects that has an oil content within the second-pass target range into the target content diverter subassembly, via the blow-off; and
further directing each first-pass small object that has an oil content within the second-pass target range into the affirmatively identified small object container via the target diverting device.

12. The method of claim 11, wherein collecting the first-pass small objects that have an oil content within the second-pass non-target range in the tentatively identified small object container comprises:
directing each first-pass small objects that has an oil content within the second-pass non-target range into a non-target content diverter subassembly of the diverter assembly of the parsing subsystem of the high throughput small object sorting system, via the blow-off; and
further directing each first-pass small object that has an oil content within the second-pass non-target range into the tentatively identified small object container via a non-target diverting device of the target content diverter subassembly.

13. The method of claim 12 further comprising:
selecting container having the subject batch of small objects disposed therein;
reading an ID tag disposed on a container via an ID tag reader of the input/output console, the ID tag providing information and data relating to the respect subject batch of small objects; and
communicating the information and data relating to the respect subject batch of small objects to the system controller for use during at least one of the first-pass and second pass operation of the high throughput small object sorting system.

14. A high throughput small object sorting system, said system comprising:
an input/output console, the input/output console comprising:
an input hopper structured and operable to receive a batch of small object for input into the sorting system; and
a system controller structured and operable to control operation of the sorting system;
an elevator subsystem, the elevator subsystem comprising:
an elevator hopper structured and operable to receive the batch of small objects from the input hopper; and
a conveyor structured and operable to convey elevator hopper from a loading position to an offloading position;
a singulating and data collection subsystem, the singulating and data collection subsystem comprising:
a magnetic resonance imaging (MRI) device;
a singulator hopper structured and operable to receive the small objects from an elevator hopper; and
a singulator structured and operable to parse the small objects one-by-one from the singulator hopper and drop each small object into the MRI device such that each small object free-falls into and through the MRI device;
wherein, the magnetic resonance imaging (MRI) device structured and operable to receive each small object from the singulator, determine total mass data and oil mass data of each small object received by the MRI device, and communicate the total mass and oil mass data for each small object received by the MRI device to the system controller as each small object free-falls through the MRI device; and
a parsing subsystem, the parsing subsystem comprising:
a diverter assembly structured and operable to direct each small object to one of a discard bin, an affirmatively identified small object container, a tentatively identified small object container, or the elevator hopper based on an oil content of each small object determined by the system controller utilizing the total mass and oil mass data.

15. The system of claim 14, wherein the input/output console further comprises at least one of:
a scale structured and operable to measure the weight of a plurality of the batch of small objects prior to depositing the batch of small objects into the input hopper;
an ID tag reader structured and operable to read an ID tag disposed on a small object container having the batch of small objects disposed therein; and
a label printer structured and operable to print an ID label that provides information and data regarding a target batch of small objects produced via operation of the small object sorting system.

16. The system of claim 14, wherein the parsing subsystem further comprises:
an inlet tube structured and operable to receive the small objects from the MRI device;
a target content diverter subassembly connected to the inlet tube;
a non-target content diverter subassembly connected to the inlet tube; and
a blow-off structured and operable to:
direct small objects that have a target oil content into a the target content diverter subassembly; and
direct small objects that have non-target oil content into the non-target content diverter subassembly.

17. The system of claim 16, wherein the target content diverter subassembly comprises:
a receiving conduit structured and operable to receive small objects from the inlet tub that have the target oil content; and
a first Y-channel box connected to the receiving conduit, the first Y-channel box structured and operable to direct the small objects that have the target oil content into one of a second-pass return tube and the affirmatively identified small object container.

18. The system of claim 17, wherein the first Y-channel box comprises:
a first Y-shaped hollow channel having a first arm and a second arm; and
a target diverting device disposed between the first arm and the second arm, the target diverting device structured and operable to direct the small objects that have the target oil content into one of:
the first arm during a first-pass operation of the small object sorting system; and
the second arm during a second-pass operation of the small object sorting system.

19. The system of claim 17, wherein the non-target content diverter subassembly comprises a second Y-channel box structured and operable to receive small objects from the inlet tube that have the non-target oil content, and to direct the small objects that have the non-target oil content into one of a discard bin hopper and the tentatively identified small object container.

20. The system of claim 19, wherein the second Y-channel box comprises:
a second Y-shaped hollow channel having a first arm and a second arm; and
a non-target diverting device disposed between the first arm and the second arm, the target diverting device structured and operable to direct the small objects that have the non-target oil content into one of:
the first arm during a first-pass operation of the small object sorting system; and
the second arm during a second-pass operation of the small object sorting system.
